(19) United States
(12) Patent Application Publication
(10) Pub. No.: US 2023/0391939 A1
(43) Pub. Date: Dec. 7, 2023

(54) RESIN COMPOSITION, PREPREG, LAMINATED PLATE, RESIN FILM, PRINTED WIRING BOARD, AND SEMICONDUCTOR PACKAGE

(71) Applicant: SHOWA DENKO MATERIALS CO., LTD., Tokyo (JP)

(72) Inventors: Kohta IWANAGA, Tokyo (JP); Tomohiko KOTAKE, Tokyo (JP); Tomoaki TSUKAHARA, Tokyo (JP); Takayuki SUZUKI, Tokyo (JP); Shota NAKAMURA, Tokyo (JP)

(21) Appl. No.: 18/259,444

(22) PCT Filed: Dec. 24, 2021
(86) PCT No.: PCT/JP2021/048276

§ 371 Date: Jun. 27, 2023

(30) Foreign Application Priority Data
Dec. 28, 2020 (JP) 2020-218893

(51) Int. Cl. C08F 257/02; C08L 51/06; C08J 5/24; H05K 1/03; H05K 3/46; H05K 1/18

(52) U.S. Cl. CPC C08F 257/02; C08L 51/06; C08J 5/24; H05K 1/0353; H05K 3/4652; H05K 1/18; C08J 2351/06; C08L 2203/16; C08L 2203/20

(57) ABSTRACT

The present invention relates to a resin composition containing (A) at least one selected from the group consisting of a maleimide compound including a fused ring of an aromatic ring and an aliphatic ring in the molecular structure thereof, and having two or more N-substituted maleimide groups, and its derivative, and (B) a resin having a tensile elastic modulus of 10 GPa or less at 25° C., and a prepreg, a laminated plate, a resin film, a printed wiring board, and a semiconductor package which use the resin composition.

### TECHNICAL FIELD

The present embodiment relates to a resin composition, a prepreg, a laminated plate, a resin film, a printed wiring board, and a semiconductor package.

### BACKGROUND ART

In mobile communication devices such as mobile phones, base stations thereof, network infrastructure devices such as servers and routers, and electronic devices such as large computers, the speed and capacity of signals used are increasing year by year. Along with this, substrate materials for printed wiring boards mounted in these electronic devices are required to have dielectric characteristics [hereinafter sometimes referred to as “high-frequency characteristics”.] capable of reducing transmission loss of high-frequency signals, that is, a low dielectric constant and a low dielectric loss tangent.

In recent years, in addition to the electronic devices mentioned above, new systems that handle high-frequency wireless signals have been put to practical use or planned for practical use in the field of ITS (Intelligent Transport Systems), such as those related to automobiles and transportation systems, and in the field of indoor short-distance communication. Therefore, it is expected that there will be an increasing need for substrate materials with excellent high-frequency characteristics for printed wiring boards used in these fields in the future.

With an aim to provide a thermosetting resin composition that has a low dielectric loss tangent, and a low thermal expansion, and is excellent in wiring embeddability and flatness, PTL 1 discloses a technique of blending a polybutadiene-based elastomer modified with an acid anhydride, in a thermosetting resin composition that contains an inorganic filler, and a polyimide compound having a maleimide compound-derived structural unit having at least two N-substituted maleimide groups and a diamine compound-derived structural unit.

### CITATION LIST

### Patent Literature

PTL 1: JP 2018-012747 A

### SUMMARY OF INVENTION

### Technical Problem

By the way, in recent years, substrate materials are required to be applied to fifth-generation mobile communication system (5G) antennas that use radio waves in the frequency band exceeding 6 GHz and millimeter wave radars that use radio waves in the frequency band of 30 to 300 GHz. For this purpose, it is necessary to develop a resin composition with further improved dielectric characteristics in a band of 10 GHz or higher.

As a method of reducing transmission loss, a method of decreasing the contact area between an insulating layer and a conductor formed on the insulating layer is also effective. However, the decrease in the contact area between the insulating layer and the conductor may cause a reduction in adhesion between the insulating layer and the conductor. Thus, it has been difficult to achieve both the dielectric characteristics and the adhesion to conductors to a high extent.

The thermosetting resin composition disclosed in PTL 1 is excellent in dielectric characteristics, but there is room for improvement in terms of achieving both better dielectric characteristics and adhesion to conductors.

In consideration of such a current situation, an object of the present embodiment is to provide a resin composition excellent in dielectric characteristics and adhesion to conductors in a high frequency band of a 10 GHz band or higher, and a prepreg, a laminated plate, a resin film, a printed wiring board, and a semiconductor package, which use the resin composition.

### Solution to Problem

The present inventors conducted studies to solve the above problem, and as a result, it has been found that the problems can be solved by the present embodiment described below.

That is, the present embodiment relates to the followings [1] to [11].

[1] A resin composition containing:
(A) at least one selected from the group consisting of a maleimide compound including a fused ring of an aromatic ring and an aliphatic ring in the molecular structure thereof, and including two or more N-substituted maleimide groups, and its derivative; and
(B) a resin having a tensile elastic modulus of 10 GPa or less at 25° C.

[2] The resin composition described in [1], in which the fused ring is an indane ring.

[3] The resin composition described in [2], in which the indane ring is a divalent group represented by the following formula (a1-1) and is included in the component (A),

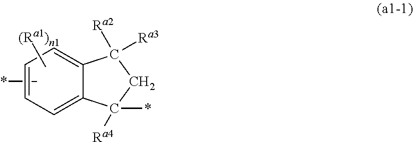

wherein R^{a1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group or a mercapto group, and n1 is an integer of 0 to 3, each of R^{a2} to R^{a4} is independently an alkyl group having 1 to 10 carbon atoms, and * represents a bonding site.

[4] The resin composition described in any one of [1] to [3], in which the component (B) contains at least one selected from the group consisting of a polyolefin-based resin, a polyphenylene ether-based resin, a silicon-based resin and an epoxy resin.

[5] The resin composition described in [4], in which the component (B) contains, as the polyolefin-based resin, a modified conjugated diene polymer obtained by modifying (b1) a conjugated diene polymer having a vinyl group in a side chain, with (b2) a maleimide compound having two or more N-substituted maleimide groups.

[6] The resin composition described in [4] or [5], in which the component (B) contains a styrene-based elastomer as the polyolefin-based resin.

[7] A prepreg containing the resin composition described in any one of [1] to [6] or a semi-cured product of the resin composition.

[8] A laminated plate including a cured product of the resin composition described in any one of [1] to [6] or a cured product of the prepreg described in [7], and metal foil.

[9] A resin film containing the resin composition described in any one of [1] to [6] or a semi-cured product of the resin composition.

[10] A printed wiring board including at least one selected from the group consisting of a cured product of the resin composition described in any one of [1] to [6], a cured product of the prepreg described in [7], and the laminated plate described in [8].

[11] A semiconductor package including the printed wiring board described in [10], and a semiconductor element.

### Advantageous Effects of Invention

According to the present embodiment, it is possible to provide a resin composition excellent in dielectric characteristics and adhesion to conductors in a high frequency band of a 10 GHz band or higher, and a prepreg, a laminated plate, a resin film, a printed wiring board, and a semiconductor package, which use the resin composition.

### DESCRIPTION OF EMBODIMENTS

In the present specification, a numerical value range expressed using “to” indicates a range including the numerical values before and after “to” as the minimum and maximum values, respectively.

A lower limit and an upper limit of a numerical value range described in the present specification can be arbitrarily combined with lower and upper limits of other numerical value ranges, respectively.

In the numerical value ranges described in the present specification, the upper limit or lower limit of a numerical value range may be replaced with values shown in the Examples.

Each component and material exemplified in the present specification may be used alone or in combination of two or more thereof unless otherwise specified.

In the present specification, unless otherwise specified, the content of each component in the resin composition means, when there are a plurality of substances corresponding to each component in the resin composition, the total amount of the plurality of substances present in the resin composition.

Aspects in which the items described in the present specification are arbitrarily combined are also included in the present embodiment.

The mechanism of action described in the present specification is an assumption, and does not limit the mechanism of the effect of the resin composition according to the present embodiment.

The term “compatible” in this specification means that resins are miscible with each other on a nano basis or a micro basis or in appearance, even if the resins are not necessarily compatible on a molecular basis.

A “semi-cured product” in this specification is synonymous with a resin composition in a state of B-stage in accordance with JIS K 6800 (1985), and a “cured product” is synonymous with a resin composition in a state of C-stage in accordance with JIS K 6800 (1985).

The number average molecular weight in the present specification means a value measured in terms of polystyrene by gel permeation chromatography (GPC), and specifically the number average molecular weight in the present specification can be measured by the method described in Examples.

[Resin Composition]

A resin composition of the present embodiment is a resin composition containing:
(A) at least one selected from the group consisting of a maleimide compound including a fused ring of an aromatic ring and an aliphatic ring in the molecular structure thereof, and including two or more N-substituted maleimide groups, and its derivative [hereinafter, referred to as a “component (A)” in some cases], and
(B) a resin having a tensile elastic modulus of 10 GPa or less at 25° C. [hereinafter, simply referred to as a “25° C. tensile elastic modulus” in some cases][hereinafter, referred to as a “component (B)” in some cases].

The reason why the resin composition of the present embodiment is excellent in dielectric characteristics and adhesion to conductors [hereinafter, referred to as “conductor adhesiveness” in some cases] in a high frequency band of a 10 GHz band or higher is not clear but is presumed as follows.

The component (A) contained in the resin composition of the present embodiment is a maleimide compound including a fused ring of an aromatic ring and an aliphatic ring in the molecular structure thereof. It is thought that the fused ring includes the aliphatic ring with a low polarity in its structure, and thus contributes to reduction of a dielectric loss tangent of a cured product obtained from the resin composition of the present embodiment, and its bulky steric structure contributes to reduction of a dielectric constant. Further, since the fused ring included in the component (A) locally lowers the polarity of the maleimide compound, the component (A) tends to have excellent compatibility with a low polar compound as well as a highly polar compound. This improves the homogeneity of the entire cured product obtained from the resin composition of the present embodiment, and thus, it is thought that the conductor adhesiveness is also improved.

Further, the component (B) contained in the resin composition of the present embodiment has a tensile elastic modulus of 10 GPa or less at 25° C. The resin that satisfies the 25° C. tensile elastic modulus has excellent compatibility with the component (A) in terms of the rigidity, molecular weight, polarity, etc. of the resin and can contribute to the improvement of dielectric characteristics. Thus, it is thought that the dielectric characteristics are further improved.

<Component (A)>

The component (A) is at least one selected from the group consisting of a maleimide compound including a fused ring of an aromatic ring and an aliphatic ring in the molecular structure thereof, and including two or more N-substituted maleimide groups, and its derivative.

The component (A) may be used alone or in combination of two or more thereof.

From the viewpoint of dielectric characteristics and conductor adhesiveness, the component (A) is preferably at least one compound selected from the group consisting of the followings (i) and (ii).
(i) a maleimide compound (a1) containing a fused ring of an aromatic ring and an aliphatic ring in the molecular structure thereof, and including two or more N-substituted maleimide groups [hereinafter, referred to as a “maleimide compound (a1)” or a “component (a1)” in some cases]
(ii) an aminomaleimide compound having a structural unit derived from a maleimide compound (a1) and a structural unit derived from a diamine compound (a2) [hereinafter, referred to as an “aminomaleimide compound (A1)” or a “component (A1)” in some cases]

(Maleimide Compound (a1))

From the viewpoint of dielectric characteristics, conductor adhesiveness and heat resistance, the component (a1) is preferably an aromatic maleimide compound that includes a fused ring of an aromatic ring and an aliphatic ring in the molecular structure thereof, and has two or more N-substituted maleimide groups. Further, the component (a1) is more preferably an aromatic bismaleimide compound that includes a fused ring of an aromatic ring and an aliphatic ring in the molecular structure thereof, and has two N-substituted maleimide groups.

In the present specification, the “aromatic maleimide compound” means a compound having an N-substituted maleimide group directly bonded to an aromatic ring, and the “aromatic bismaleimide compound” means a compound including two N-substituted maleimide groups directly bonded to an aromatic ring.

The fused ring included in the component (a1) preferably has a condensed bicyclic structure, and is more preferably an indane ring, from the viewpoint of dielectric characteristics, conductor adhesiveness and ease of production.

The component (a1) including the indane ring is preferably an aromatic bismaleimide compound containing the indane ring.

In the present specification, the indane ring means a condensed bicyclic structure of a 6-membered aromatic ring and a 5-membered saturated aliphatic ring. Among ring carbon atoms forming the indane ring, at least one carbon atom has a bonding group for bonding to another group constituting the component (a1). The ring carbon atom having the bonding group and other ring carbon atoms may not have a bonding group, a substituent, etc. other than the bonding group, but preferably have the other bonding group, thereby forming a divalent group.

In the component (a1), the indane ring is preferably contained as a divalent group represented by the following formula (a1-1).

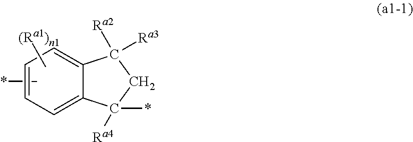

(In the formula, R^{a1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group or a mercapto group, and n1 is an integer of 0 to 3. Each of R^{a2} to R^{a4} is independently an alkyl group having 1 to 10 carbon atoms. * represents a bonding site.)

Examples of the alkyl group having 1 to 10 carbon atoms and represented by R^{a1} in the formula (a1-1) include a methyl group, an ethyl group, a propyl group, a butyl group, a pentyl group, a hexyl group, a heptyl group, an octyl group, a nonyl group, and a decyl group. These alkyl groups may be either linear or branched.

Examples of the alkyl group included in the alkyloxy group having 1 to 10 carbon atoms and the alkylthio group having 1 to 10 carbon atoms, which are represented by R^{a1}, include the same as those for the alkyl group having 1 to 10 carbon atoms.

Examples of the aryl group having 6 to 10 carbon atoms and represented by R^{a1} include a phenyl group, and a naphthyl group.

Examples of the aryl group included in the aryloxy group having 6 to 10 carbon atoms and the arylthio group having 6 to 10 carbon atoms, which are represented by R^{a1}, include the same as those for the aryl group having 6 to 10 carbon atoms.

Examples of the cycloalkyl group having 3 to 10 carbon atoms and represented by R^{a1} include a cyclopropyl group, a cyclobutyl group, a cyclopentyl group, a cyclohexyl group, a cycloheptyl group, a cyclooctyl group, a cyclononyl group, and a cyclodecyl group.

From the viewpoint of solvent solubility and reactivity, when n1 in the formula (a1-1) is an integer of 1 to 3, R^{a1} is preferably an alkyl group having 1 to 4 carbon atoms, a cycloalkyl group having 3 to 6 carbon atoms, or an aryl group having 6 to 10 carbon atoms, more preferably an alkyl group having 1 to 4 carbon atoms.

Examples of the alkyl group having 1 to 10 carbon atoms and represented by R^{a2} to R^{a4} include a methyl group, an ethyl group, a propyl group, a butyl group, a pentyl group, a hexyl group, a heptyl group, an octyl group, a nonyl group, and a decyl group. These alkyl groups may be either linear or branched. Among these, an alkyl group having 1 to 4 carbon atoms is preferable for R^{a2} to R^{a4}, a methyl group and an ethyl group are more preferable, and a methyl group is further preferable.

n1 in the formula (a1-1) is an integer of 0 to 3. When n1 is 2 or 3, R^{a1}'s may be the same or different.

From the viewpoint of ease of production, among the above, the divalent group represented by the formula (a1-1) is preferably a divalent group represented by the following formula (a1-1′) in which n1 is 0, and R^{a2} to R^{a4} are methyl groups.

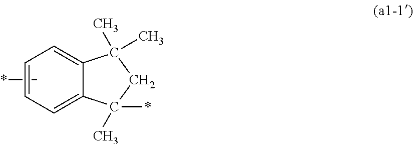

(In the formula, * represents a bonding site.)

The component (a1) including the divalent group represented by the formula (a1-1) is preferably represented by the following formula (a1-2) from the viewpoint of dielectric characteristics, conductor adhesiveness, heat resistance and ease of production.

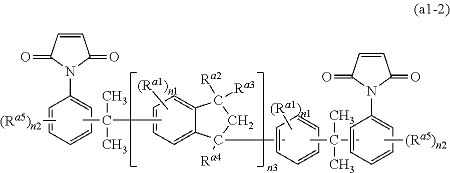

(In the formula, R^{a1} to R^{a4} and n1 are the same as those in the formula (a1-1). R^{a5} is each independently an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxy group or a mercapto group, n2 is each independently an integer of 0 to 4, and n3 is a number of 0.95 to 10.0.)

In the formula (a1-2), R^{a1}'s, n1's, R^{a5}'s, and n2's may be separately the same or different.

When n3 is greater than 1, R^{a2}'s, R^{a3}'s, and R^{a4}'s may be separately the same or different.

Examples of the alkyl group having 1 to 10 carbon atoms and represented by R^{a5} in the formula (a1-2) include a methyl group, an ethyl group, a propyl group, a butyl group, a pentyl group, a hexyl group, a heptyl group, an octyl group, a nonyl group, and a decyl group. These alkyl groups may be either linear or branched.

Examples of the alkyl group included in the alkyloxy group having 1 to 10 carbon atoms and the alkylthio group having 1 to 10 carbon atoms, which are represented by R^{a5}, include the same as those for the alkyl group having 1 to 10 carbon atoms.

Examples of the aryl group having 6 to 10 carbon atoms and represented by R^{a5} include a phenyl group, and a naphthyl group.

Examples of the aryl group included in the aryloxy group having 6 to 10 carbon atoms and the arylthio group having 6 to 10 carbon atoms, which are represented by R^{a5}, include the same as those for the aryl group having 6 to 10 carbon atoms.

Examples of the cycloalkyl group having 3 to 10 carbon atoms and represented by R^{a5} include a cyclopropyl group, a cyclobutyl group, a cyclopentyl group, a cyclohexyl group, a cycloheptyl group, a cyclooctyl group, a cyclononyl group, and a cyclodecyl group.

From the viewpoint of solvent solubility and ease of production, among these, an alkyl group having 1 to 4 carbon atoms, a cycloalkyl group having 3 to 6 carbon atoms, and an aryl group having 6 to 10 carbon atoms are preferable for R^{a5}, an alkyl group having 1 to 3 carbon atoms is more preferable, and a methyl group is further preferable.

n2 in the formula (a1-2) is an integer of 0 to 4, and is preferably an integer of 0 to 3, more preferably 0 or 2 from the viewpoint of compatibility with other resins, dielectric characteristics, conductor adhesiveness and ease of production.

When n2 is 1 or more, the benzene ring and the N-substituted maleimide group have a twisted conformation, which tends to further improve solvent solubility by suppressing intermolecular stacking. From the viewpoint of suppressing the intermolecular stacking, when n2 is 1 or more, the substitution position of R^{a5} is preferably an ortho position relative to the N-substituted maleimide group.

n3 in the formula (a1-2) is preferably a value of 0.98 to 8.0, more preferably a value of 1.0 to 7.0, further preferably a value of 1.1 to 6.0 from the viewpoint of dielectric characteristics, conductor adhesiveness, solvent solubility, handling properties and heat resistance. n3 represents the average number of structural units including indane rings.

The component (a1) represented by the formula (a1-2) is more preferably represented by the following formula (a1-3) or represented by the following formula (a1-4) from the viewpoint of dielectric characteristics, conductor adhesiveness, solvent solubility, and ease of production.

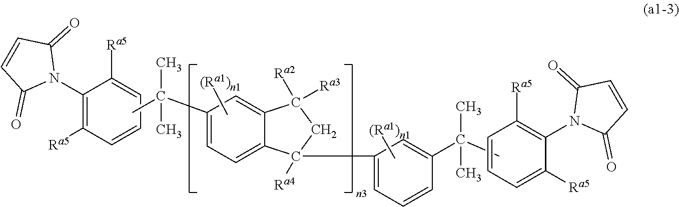

(In the formula, R^{a1} to R^{a5}, n1 and n3 are the same as those in the formula (a1-2).)

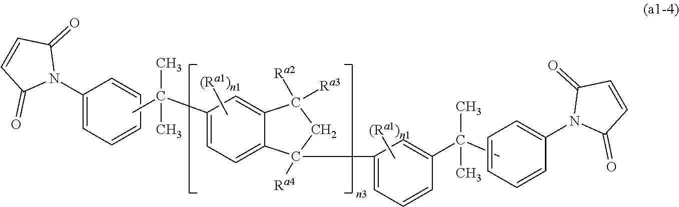

(In the formula, R^{a1} to R^{a4}, n1 and n3 are the same as those in the formula (a1-2).)

Examples of the component (a1) represented by the formula (a1-3) include a compound represented by the following formula (a1-3-1), a compound represented by the following formula (a1-3-2), and a compound represented by the following formula (a1-3-3).

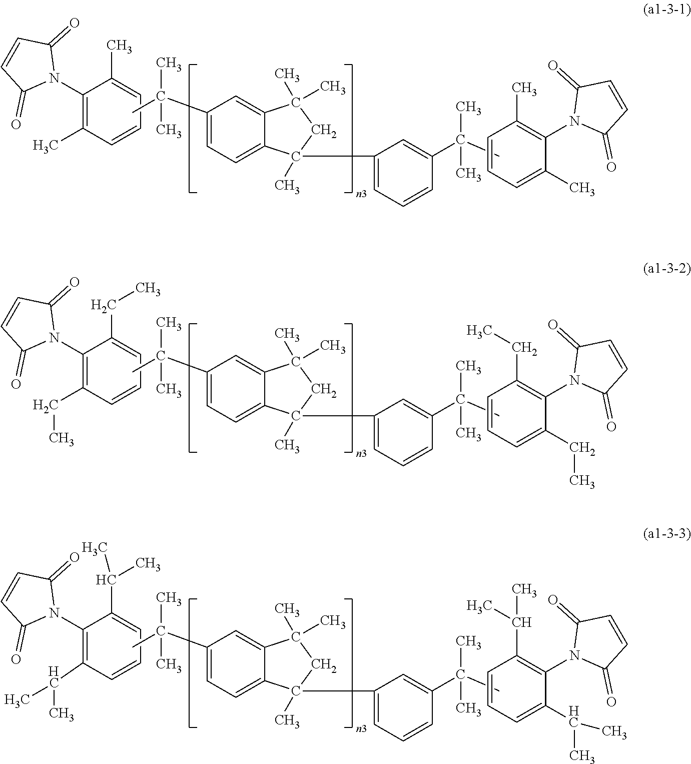

(In the formula, n3 is the same as that in the formula (a1-2).)

Examples of the compound represented by the formula (a1-4) include a compound represented by the following formula (a1-4-1).

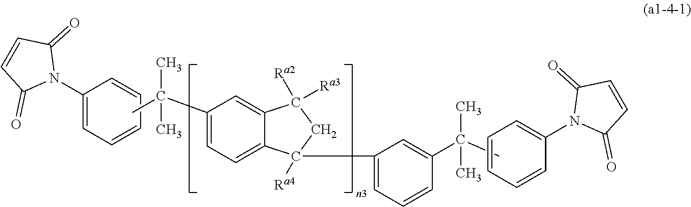

(In the formula, n3 is the same as that in the formula (a1-2).)

The number average molecular weight of the component (a1) is not particularly limited, but is preferably 600 to 3,000, more preferably 800 to 2,000, further preferably 1,000 to 1,500 from the viewpoint of compatibility with other resins, conductor adhesiveness and heat resistance.

The component (a1) can be produced by, for example, a method of carrying out a reaction of an intermediate amine compound including a fused ring of an aromatic ring and an aliphatic ring [hereinafter, simply abbreviated as an “intermediate amine compound” in some cases] with maleic anhydride [hereinafter, referred to as a “maleimidation reaction” in some cases].

Hereinafter, descriptions will be made on the production method of the component (a1) by taking a maleimide compound including an indane ring as a fused ring of an aromatic ring and an aliphatic ring, as an example.

The intermediate amine compound of the indane ring-containing maleimide compound can be obtained as a compound represented by the following formula (a1-7) by performing, for example, a reaction [hereinafter, referred to as a “cyclization reaction” in some cases] between a compound represented by the following formula (a1-5) [hereinafter, referred to as a “compound A” in some cases], and a compound represented by the following formula (a1-6) [hereinafter, referred to as a “compound B” in some cases], in the presence of an acid catalyst.

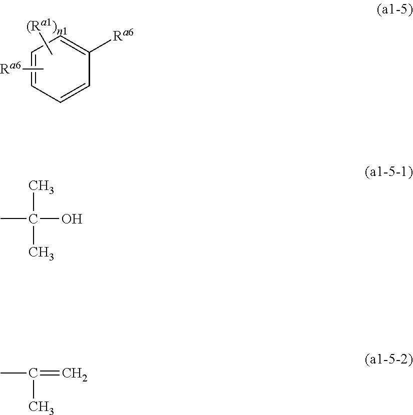

(In the formula, R^{a1} and n1 are the same as those in the formula (a1-1). R^{a6} is each independently a group represented by the formula (a1-5-1) or the formula (a1-5-2), and the ortho position of at least one R^{a6} of two R^{a6}'s is a hydrogen atom.)

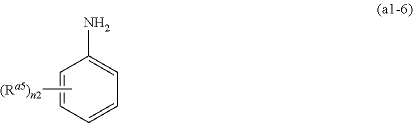

(In the formula, R^{a5} and n2 are the same as those in the formula (a1-2). Meanwhile, at least one of the ortho position and the para position of the amino group is a hydrogen atom.)

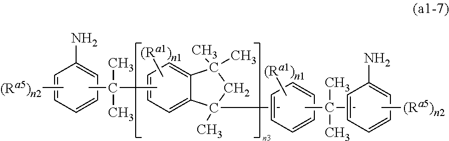

(In the formula, R^{a1}, R^{a5}, and n1 to n3 are the same as those in the formula (a1-2).)

Examples of the compound A include p- or m-diisopropenylbenzene, p- or m-bis(α-hydroxyisopropyl)benzene, 1-(α-hydroxyisopropyl)-3-isopropenylbenzene, 1-(α-hydroxyisopropyl)-4-isopropenylbenzene, mixtures thereof, nuclear alkyl group-substituted products of these compounds, and nuclear halogen-substituted products of these compounds.

Examples of the nuclear alkyl group-substituted product include diisopropenyltoluene, and bis(α-hydroxyisopropyl)toluene.

Examples of the nuclear halogen-substituted product include chlorodiisopropenylbenzene, and chlorobis(α-hydroxyisopropyl)benzene.

These compounds A may be used alone or in combination of two or more thereof.

Examples of the compound B include aniline, dimethylaniline, diethylaniline, diisopropylaniline, ethylmethylaniline, cyclobutylaniline, cyclopentylaniline, cyclohexylaniline, chloroaniline, dichloroaniline, toluidine, xylidine, phenylaniline, nitroaniline, aminophenol, methoxyaniline, ethoxyaniline, phenoxyaniline, naphthoxyaniline, aminothiol, methylthioaniline, ethylthioaniline, and phenylthioaniline. These compounds B may be used alone or in combination of two or more thereof.

In the cyclization reaction, for example, the compound A and the compound B are prepared at such a ratio that the molar ratio between the two (compound B/compound A) is preferably 0.1 to 2.0, more preferably 0.15 to 1.5, further preferably 0.2 to 1.0, and then a first stage reaction is performed.

Next, it is desirable that the compound B to be further added is added such that its molar ratio to the previously added compound A (compound B to be added/compound A) is preferably a ratio of 0.5 to 20, more preferably 0.6 to 10, further preferably 0.7 to 5, and then a second stage reaction is performed.

Examples of the acid catalyst used for the cyclization reaction include: inorganic acids such as phosphoric acid, hydrochloric acid, and sulfuric acid; organic acids such as oxalic acid, benzenesulfonic acid, toluene sulfonic acid, methane sulfonic acid, and fluoromethane sulfonic acid; solid acids such as activated clay, acidic clay, silica alumina, zeolite, and strongly acidic ion exchange resin; and heteropolyhydrochloric acid. These may be used alone or in combination of two or more thereof.

The amount of the acid catalyst to be blended is preferably 5 to 40 parts by mass, more preferably 5 to 35 parts by mass, further preferably 5 to 30 parts by mass with respect to 100 parts by mass as the total amount of the compound A and the compound B which are initially prepared, from the viewpoint of reaction rate and reaction uniformity.

The reaction temperature of the cyclization reaction is preferably 100 to 300° C., more preferably 130 to 250° C., further preferably 150 to 230° C. from the viewpoint of reaction rate and reaction uniformity.

The reaction time of the cyclization reaction is preferably 2 to 24 h, more preferably 4 to 16 h, further preferably 8 to 12 h from the viewpoint of productivity and sufficient progress of the reaction.

Meanwhile, these reaction conditions can be appropriately adjusted according to the types of raw materials to be used, and the like, and are not particularly limited.

During the cyclization reaction, as necessary, a solvent such as toluene, xylene, or chlorobenzene may be used. Further, when water is produced as a by-product during the cyclization reaction, a dehydration reaction may be facilitated by using a solvent capable of performing azeotropic dehydration.

Next, the above-obtained intermediate amine compound is reacted with maleic anhydride in an organic solvent so as to perform a maleimidation reaction in which a primary amino group included in the intermediate amine compound is converted into a maleimide group. The component (a1) can be obtained by carrying out this maleimidation reaction.

In the maleimidation reaction, the ratio of the equivalent of maleic anhydride to the equivalent of the primary amino group of the intermediate amine compound (maleic anhydride/primary amino group) is not particularly limited, but is preferably 1.0 to 1.5, more preferably 1.05 to 1.3, further preferably 1.1 to 1.2 from the viewpoint of reducing the amount of unreacted primary amino groups and the amount of unreacted maleic anhydride.

The amount of the organic solvent used in the maleimidation reaction is not particularly limited, but is preferably 50 to 5,000 parts by mass, more preferably 70 to 2,000 parts by mass, further preferably 100 to 500 parts by mass with respect to 100 parts by mass as the total amount of the intermediate amine compound and the maleic anhydride from the viewpoint of reaction rate and reaction uniformity.

In the maleimidation reaction, it is preferable that the reaction between the intermediate amine compound and maleic anhydride is carried out in two stages.

The reaction temperature in the first stage reaction is preferably 10 to 100° C., more preferably 20 to 70° C., further preferably 30 to 50° C.

The reaction time in the first stage reaction is preferably 0.5 to 12 h, more preferably 0.7 to 8 h, further preferably 1 to 4 h.

After the first stage reaction is ended, it is preferable that subsequent to addition of a catalyst such as toluenesulfonic acid, the second stage reaction is carried out.

The reaction temperature in the second stage reaction is preferably 90 to 130° C., more preferably 100 to 125° C., further preferably 105 to 120° C.

The reaction time in the second stage reaction is preferably 2 to 24 h, more preferably 4 to 15 h, further preferably 6 to 10 h.

Meanwhile, the reaction conditions can be appropriately adjusted according to the types of raw materials to be used, and the like, and are not particularly limited.

After the reaction, as necessary, unreacted raw materials, other impurities, etc. may be removed by performing purification such as washing with water.

The component (a1) obtained through the method may contain a maleimide compound containing no indane ring, as a by-product in some cases. The maleimide compound containing no indane ring is, for example, a compound in which n3 is 0 in the formula (a1-2).

The content of the maleimide compound containing no indane ring, as a by-product, in the reaction product, can be measured by measuring, for example, GPC of the reaction product. Specifically, for example, a calibration curve of an elution time for the number of n3 is created by using each compound of the formula (a1-2) in which n3 is 0 to 4. Then, from the elution time of the peak seen in the GPC chart of the reaction product, the numbers of n3 of the compounds included in the reaction product and the average value thereof can be grasped. Further, the content ratio of the compound having the number of n3 indicated by the peak can be grasped according to the area ratio of each peak.

In the component (a1), it is desirable that the content of the maleimide compound containing no indane ring, as the by-product, is small. Therefore, in the GPC chart of the reaction product, the ratio of the area of the maleimide compound containing no indane ring, which is a by-product, to the total peak area of the reaction product is preferably 40% or less, more preferably 30% or less, further preferably 20% or less, particularly preferably 10% or less.

(Aminomaleimide Compound (A1))

The aminomaleimide compound (A1) is an aminomaleimide compound having a structural unit derived from a maleimide compound (a1) and a structural unit derived from a diamine compound (a2). The component (A1) corresponds to a derivative of the maleimide compound (a1).

The component (A1) may be used alone or in combination of two or more thereof.

[Structural Unit Derived from Maleimide Compound (a1)]

Examples of the structural unit derived from the component (a1) include a structural unit obtained by the Michael addition reaction of at least one N-substituted maleimide group among the N-substituted maleimide groups of the component (a1) with the amino group of the diamine compound (a2).

The structural unit derived from the component (a1) contained in the component (A1) may be of one kind alone, or may be of two or more kinds thereof.

The content of the structural unit derived from the component (a1) in the aminomaleimide compound (A1) is not particularly limited; however, it is preferably 5 to 95% by mass, more preferably 30 to 93% by mass, and still more preferably 60 to 90% by mass. When the content of the structural unit derived from the component (a1) in the component (A1) is within the aforementioned range, the dielectric characteristics and film handling properties tend to be further improved.

[Structural Unit Derived from Diamine Compound (a2)]

Examples of the structural unit derived from the component (a2) include a structural unit obtained by the Michael addition reaction of one or both of the two amino groups of the component (a2) with the N-substituted maleimide group of the maleimide compound (a1).

The structural unit derived from the component (a2) contained in the component (A1) may be of one kind alone, or may be of two or more kinds thereof.

The amino group of the component (a2) is preferably a primary amino group.

Examples of the structural unit derived from the diamine compound (a2) having two primary amino groups include a group represented by the following general formula (a2-1) and a group represented by the following general formula (a2-2).

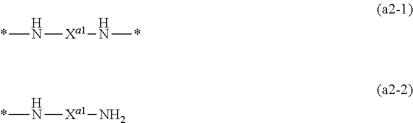

(In the formula, X^{a1} is a divalent organic group, and * indicates a bonding position to another structure.)

X^{a1} in the above general formulas (a2-1) and (a2-2) is a divalent organic group and corresponds to a divalent group obtained by removing two amino groups from the component (a2).

X^{a1} in the above general formulas (a2-1) and (a2-2) is preferably a divalent group represented by the following general formula (a2-3).

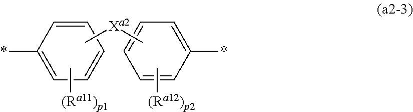

(In the formula, R^{a11} and R^{a12} each are independently an aliphatic hydrocarbon group having 1 to 5 carbon atoms, an alkoxy group having 1 to 5 carbon atoms, a hydroxy group, or a halogen atom. X^{a2} is a an alkylene group, having 1 to 5 carbon atoms, an alkylidene group having 2 to 5 carbon atoms, an ether group, a sulfide group, a sulfonyl group, a carbonyloxy group, a keto group, a fluorenylene group, a single bond, or a divalent group represented by the following general formula (a2-3-1) or (a2-3-2); p1 and p2 each are independently an integer of 0 to 4; * represents a bonding site.)

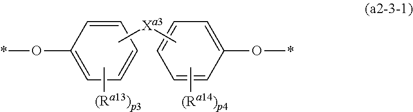

(In the formula, R^{a13} and R^{a14} each are independently an aliphatic hydrocarbon group having 1 to 5 carbon atoms or a halogen atom. X^{a3} is an alkylene group having 1 to 5 carbon atoms, an alkylidene group having 2 to 5 carbon atoms, an m-phenylenediisopropylidene group, a p-phenylenediisopropylidene group, an ether group, a sulfide group, a sulfonyl group, a carbonyloxy group, a keto group or a single bond; p3 and p4 each are independently an integer of 0 to 4; * represents a bonding site.)

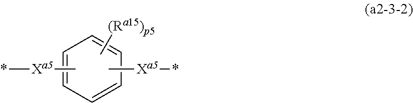

(In the formula, R^{a15} is an aliphatic hydrocarbon group having 1 to 5 carbon atoms or a halogen atom. X^{a4} and X^{a5} each are independently an alkylene group having 1 to 5 carbon atoms, an alkylidene group having 2 to 5 carbon atoms, an ether group, a sulfide group, a sulfonyl group, a carbonyloxy group, a keto group, or a single bond; p5 is an integer of 0 to 4; * represents a bonding site.)

Examples of the aliphatic hydrocarbon group having 1 to 5 carbon atoms and represented by R^{a11}, R^{a12}, R^{a13}, R^{a14} and R^{a15} in the formula (a2-3), the formula (a2-3-1) and the formula (a2-3-2) include: alkyl groups having 1 to 5 carbon atoms such as a methyl group, an ethyl group, an n-propyl group, an isopropyl group, an n-butyl group, an isobutyl group, a t-butyl group, and an n-pentyl group; alkenyl groups having 2 to 5 carbon atoms, and alkynyl groups having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, further preferably a methyl group or an ethyl group.

Examples of the halogen atom include a fluorine atom, a chlorine atom, a bromine atom, and an iodine atom.

Examples of the alkylene group having 1 to 5 carbon atoms and represented by X^{a2} in the formula (a2-3), X^{a3} in the formula (a2-3-1), and X^{a4} and X^{a5} in the formula (a2-3-2) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, further preferably a methylene group.

Examples of the alkylidene group having 2 to 5 carbon atoms represented by X^{a2} in the above general formula (a2-3), X^{a3} in the above general formula (a2-3-1), and X^{a4} and X^{a5} in the above general formula (a2-3-2) include an ethylidene group, a propylidene group, an isopropylidene group, a butylidene group, an isobutylidene group, a pentylidene group, and an isopentylidene group. The alkylidene group having 2 to 5 carbon atoms is preferably an alkylidene group having 2 to 4 carbon atoms, more preferably an alkylidene group having 2 or 3 carbon atoms, further preferably an isopropylidene group.

In the general formula (a2-3), p1 and p2 each are independently an integer of 0 to 4, and from the viewpoint of availability, both of p11 and p12 are preferably integers of 0 to 3, more preferably 0 to 2, and still more preferably 0 or 2.

When p1 and p2 are integers of 2 or more, the plurality of R^{a11}'s or R^{a1}'s may be the same or different, respectively.

In the general formula (a2-3-1), p3 and p4 each are independently an integer of 0 to 4, and from the viewpoint of availability, both of p3 and p4 are preferably integers of 0 to 2, more preferably 0 or 1, and still more preferably 0.

When p3 and p4 are integers of 2 or more, the plurality of R^{a13}'s or R^{a14}'s may be the same or different, respectively.

In the general formula (a2-3-2), p5 is an integer of 0 to 4, and from the viewpoint of availability, is preferably an integer of 0 to 2, more preferably 0 or 1, and still more preferably 0. When p5 is an integer of 2 or more, the plurality of R^{a15}'s may be the same or different, respectively.

The content of the component (a2)-derived structural units in the aminomaleimide compound (A1) is not particularly limited, but is preferably 5 to 95% by mass, more preferably 7 to 70% by mass, further preferably 10 to 40% by mass. When the content of the component (a2)-derived structural units in the aminomaleimide compound (A1) falls within the above range, the dielectric characteristics, the heat resistance, the flame retardancy and the glass transition temperature tend to be better.

Examples of the component (a2) include 4,4′-diaminodiphenylmethane, 4,4′-diamino-3,3′-dimethyldiphenylmethane, 4,4′-diamino-3,3′-diethyldiphenylmethane, 4,4′-diaminodiphenyl ether, 4,4′-diaminodiphenyl sulfone, 3,3′-diaminodiphenyl sulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl)propane, 3,3′-dimethyl-5,5′-diethyl-4,4′-diaminodiphenylmethane, 2,2-bis(4-aminophenyl)propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 1,3-bis[1-[4-(4-aminophenoxy)phenyl]-1-methylethyl]benzene, 1,4-bis[1-[4-(4-aminophenoxy)phenyl]-1-methylethyl]benzene, 4,4′-[1,3-phenylenebis(1-methylethylidene)]bisaniline, 4,4′-[1,4-phenylenebis(1-methylethylidene)]bisaniline, 3,3′-[1,3-phenylenebis(1-methylethylidene)]bisaniline, bis[4-(4-aminophenoxy)phenyl]sulfone, bis[4-(3-aminophenoxy)phenyl]sulfone, and 9,9-bis(4-aminophenyl)fluorene.

Of these, the component (a2) is preferably 4,4′-diaminodiphenylmethane, 4,4′-diamino-3,3′-dimethyldiphenylmethane, 4,4′-diamino-3,3′-diethyldiphenylmethane, 2,2-bis[4-(4-aminophenoxy)phenyl]propane, 4,4′-[1,3-phenylenebis(1-methylethylidene)]bisaniline and 4,4′-[1,4-phenylenebis(1-methylethylidene)]bisaniline from the viewpoint of excellent solubility in an organic solvent, reactivity with the maleimide compound (a1), and heat resistance. Further, the component (a2) is preferably 3,3′-dimethyl-5,5′-diethyl-4,4′-diaminodiphenylmethane from the viewpoint of excellent dielectric characteristics and low water absorption. In addition, the component (a2) is preferably 2,2-bis[4-(4-aminophenoxy)phenyl]propane from the viewpoint of excellent mechanical characteristics such as high adhesion to a conductor, elongation and breaking strength. Furthermore, from the viewpoint of excellent dielectric characteristics and low hygroscopicity in addition to excellent solubility in an organic solvent, reactivity at the time of synthesis, heat resistance, and high adhesion to a conductor, the component (a2) is preferably 4,4′-[1,3-phenylenebis(1-methylethylidene)]bisaniline and 4,4′-[1,4-phenylenebis(1-methylethylidene)]bisaniline.

In the aminomaleimide compound (A1), the equivalent ratio (Ta2/Ta1) of the total equivalent (Ta2) of groups derived from the —NH₂ group of the diamine compound (a2) (including —NH₂) to the total equivalent (Ta1) of groups derived from the N-substituted maleimide group of the maleimide compound (a1) is not particularly limited, but is preferably 0.05 to 10, more preferably 0.5 to 7, further preferably 1 to 5 from the viewpoint of dielectric characteristics, heat resistance, flame retardancy and glass transition temperature. The groups derived from the N-substituted maleimide group of the maleimide compound (a1) also include the N-substituted maleimide group itself.

The number average molecular weight of the aminomaleimide compound (A1) is not particularly limited, but is preferably 400 to 10,000, more preferably 500 to 5,000, further preferably 600 to 2,000 from the viewpoint of handleability and moldability.

(Method of Producing Aminomaleimide Compound (A1))

The component (A1) can be produced, for example, by reacting the maleimide compound (a1) with the diamine compound (a2) in an organic solvent.

By reacting the maleimide compound (a1) with the diamine compound (a2), the aminomaleimide compound (A1) is obtained through the Michael addition reaction between the maleimide compound (a1) and the diamine compound (a2).

A reaction catalyst may be used as necessary when reacting the maleimide compound (a1) and the diamine compound (a2).

Examples of the reaction catalyst include acidic catalysts such as p-toluenesulfonic acid; amines such as triethylamine, pyridine and tributylamine; imidazoles such as methylimidazole and phenylimidazole; and phosphorus catalysts such as triphenylphosphine. These may be used alone or in combination of two or more thereof.

The blending amount of the reaction catalyst is not particularly limited, but is preferably 0.01 to 5 parts by mass, more preferably 0.05 to 3 parts by mass, further preferably 0.1 to 2 parts by mass with respect to 100 parts by mass as the total amount of the maleimide compound (a1) and the diamine compound (a2) from the viewpoint of reaction rate and reaction uniformity.

The reaction temperature of the Michael addition reaction is preferably 50 to 160° C., more preferably 60 to 150° C., further preferably 70 to 140° C. from the viewpoint of workability such as a reaction rate, and suppression of gelation of a product during the reaction.

The reaction time of the Michael addition reaction is preferably 0.5 to 10 h, more preferably 1 to 8 h, further preferably 2 to 6 h from the viewpoint of productivity and sufficient progress of the reaction.

Meanwhile, these reaction conditions can be appropriately adjusted according to the types of raw materials to be used, and the like, and are not particularly limited.

In the Michael addition reaction, the solid content concentration and the solution viscosity of the reaction solution may be adjusted by adding or concentrating the organic solvent. The solid content concentration of the reaction solution is not particularly limited, but is preferably 10 to 90% by mass, more preferably 15 to 85% by mass, further preferably 20 to 80% by mass. When the solid content concentration of the reaction raw material is equal to or greater than the lower limit value, a good reaction rate is obtained, and the productivity tends to be better. Further, when the solid content concentration of the reaction raw material is equal to or smaller than the upper limit value, a better solubility is obtained, and the stirring efficiency is improved, and thus the gelation of the product during the reaction tends to be further suppressed.

<Component (B)>

The resin composition of the present embodiment contains a resin having a 25° C. tensile elastic modulus of 10 GPa or less, as the component (B), so that the dielectric characteristics and the conductor adhesiveness are improved.

In the resin composition of the present embodiment, the resin corresponding to the component (A) shall not be included in the component (B).

The component (B) may be used alone or in combination of two or more thereof.

In the present specification, the 25° C. tensile elastic modulus is a value measured by the following method.

(Measurement Method of 25° C. Tensile Elastic Modulus)

A test piece with a width of 10 mm, a length of 80 mm, and a thickness of 0.2 mm is prepared from a resin as a measurement target, and for the test piece, both ends of the test piece in a long side direction are held between upper and lower grippers such that the distance between the grippers is 60 mm. Next, by using a tensile tester, the 25° C. tensile elastic modulus of the test piece is acquired under the condition of a tensile speed of 5 mm/min, under a room temperature environment adjusted to 25° C. The calculation of the tensile elastic modulus is performed in accordance with International Standard ISO 5271 (1993).

Here, “the resin having a 25° C. tensile elastic modulus of 10 GPa or less” in the present embodiment also includes resins from which the above-mentioned test piece cannot be prepared due to a too low 25° C. tensile elastic modulus, and those which cannot be subjected to a tensile test under the conditions for the same reason even if the above-mentioned test piece can be prepared.

The 25° C. tensile elastic modulus of the component (B) is 10 GPa or less, preferably 7 GPa or less, more preferably 5 GPa or less, further preferably 3 GPa or less, still further preferably 2 GPa or less, particularly preferably 1 GPa or less, most preferably 0.6 GPa or less. When the 25° C. tensile elastic modulus of the component (B) is equal to or less than the upper limit value, the dielectric characteristics and the conductor adhesiveness of the obtained resin composition tend to be excellent.

The 25° C. tensile elastic modulus of the component (B) is not particularly limited, but is preferably 0.005 GPa or more, more preferably 0.01 GPa or more, further preferably 0.03 GPa or more. When the 25° C. tensile elastic modulus of the component (B) is equal to or greater than the lower limit value, the heat resistance and the like of the obtained resin composition tend to be satisfactorily maintained.

The number average molecular weight of the component (B) is not particularly limited, but is preferably 400 to 500,000, more preferably 600 to 350,000, further preferably 700 to 200,000. When the number average molecular weight of the component (B) is equal to or greater than the lower limit value, the heat resistance and the like of the obtained resin composition tend to be satisfactorily maintained. Further, when the number average molecular weight of the component (B) is equal to or less than the upper limit value, the dielectric characteristics and the conductor adhesiveness of the obtained resin composition tend to be excellent.

As the component (B), for example, a thermoplastic resin and its modified product may be preferably exemplified.

The component (B) may be a thermosetting resin. Then, it is desirable that a cured product of the component (B) as a thermosetting resin becomes an elastomer. Here, the “elastomer” means a polymer that has a glass transition temperature of 25° C. or less when measured by differential scanning calorimetry in accordance with JIS K 6240:2011.

Examples of the component (B) include a polyolefin-based resin, a polyphenylene ether-based resin, a silicon-based resin, an epoxy resin, a polyurethane-based resin, a polyester-based resin, a polyamide-based resin, and a polyacrylic-based resin.

Among these, the component (B) preferably contains at least one selected from the group consisting of a polyolefin-based resin, a polyphenylene ether-based resin, a silicon-based resin and an epoxy resin from the viewpoint of the compatibility with the component (A), the dielectric characteristics and the conductor adhesiveness, more preferably contains at least one selected from the group consisting of a polyolefin-based resin and a polyphenylene ether-based resin, and further preferably contains a polyolefin-based resin.

(Polyolefin-Based Resin)

The polyolefin-based resin is not particularly limited as long as it is a polyolefin-based resin having a 25° C. tensile elastic modulus of 10 GPa or less.

The polyolefin-based resin may be used alone or in combination of two or more thereof.

Examples of the polyolefin-based resin include homopolymers or copolymers of monoolefins and diolefins, and modified products thereof.

Examples of the monoolefin include ethylene, propylene, 1-butene, 1-hexene, 4-methyl-1-pentene, and styrene.

Examples of the diolefin include: nonconjugated diene compounds such as dicyclopentadiene, 1,4-hexadiene, cyclooctadiene, methylenenorbornene, and ethylidenenorbornene; and conjugated diene compounds such as 1,3-butadiene, isoprene, 1,3-pentadiene, 2,3-dimethyl-1,3-butadiene, 2-phenyl-1,3-butadiene, and 1,3-hexadiene.

As for the polyolefin-based resin, from the viewpoint of compatibility with other resins, dielectric characteristics, and conductor adhesiveness, a conjugated diene polymer (B1) [hereinafter, referred to as a “component (B1)” in some cases], a modified conjugated diene polymer (B2) [hereinafter, referred to as a “component (B2)” in some cases], and a styrene-based elastomer (B3) [hereinafter, referred to as a “component (B3)” in some cases] are preferable.

[Conjugated Diene Polymer (B1)]

The component (B1) may be a polymer of one type of conjugated diene compounds, or may be a polymer of two or more types of conjugated diene compounds.

Further, the component (B1) may be obtained by copolymerizing at least one conjugated diene compound with monomers other than at least one conjugated diene compound.

When the component (B1) is a copolymer, the polymerization mode is not particularly limited, and may be a random polymerization, a block polymerization or a graft polymerization.

The component (B1) may be used alone or in combination of two or more thereof.

The component (B1) is preferably a conjugated diene polymer having a vinyl group in the side chain, more preferably a conjugated diene polymer having a plurality of vinyl groups in the side chain, from the viewpoint of compatibility with other resins, dielectric characteristics, and conductor adhesion.

The number of vinyl groups included in one molecule of the component (B1) is not particularly limited, but is preferably 3 or more, more preferably 5 or more, further preferably 10 or more, from the viewpoint of compatibility with other resins, dielectric characteristics, and conductor adhesion. The upper limit of the number of vinyl groups included in one molecule of the component (B1) is not particularly limited, but may be 100 or less, 80 or less, or 60 or less.

Examples of the component (B1) include polybutadiene having a 1,2-vinyl group, a butadiene-styrene copolymer having a 1,2-vinyl group, and polyisoprene having a 1,2-vinyl group. Among these, from the viewpoint of dielectric characteristics and heat resistance, polybutadiene having a 1,2-vinyl group, and a butadiene-styrene copolymer having a 1,2-vinyl group are preferable, and polybutadiene having a 1,2-vinyl group is more preferable. Further, as the polybutadiene having a 1,2-vinyl group, a polybutadiene homopolymer having a 1,2-vinyl group is preferable.

The 1,2-vinyl group included in the component (B1) is a vinyl group included in a butadiene-derived structural unit represented by the following formula (B1-1).

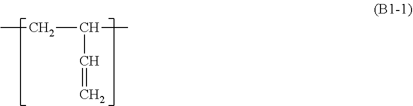

When the component (B1) is the polybutadiene having a 1,2-vinyl group, the content of structural units having a 1,2-vinyl group with respect to all butadiene-derived structural units constituting polybutadiene [hereinafter, referred to as a “vinyl group content” in some cases] is not particularly limited, but is preferably 50 mol % or more, more preferably 70 mol % or more, further preferably 85 mol % or more from the viewpoint of compatibility with other resins, dielectric characteristics, conductor adhesiveness, and heat resistance. Further, the upper limit of the vinyl group content is not particularly limited, and may be 100 mol % or less, 95 mol % or less, or 90 mol % or less. The structural unit having a 1,2-vinyl group is preferably the butadiene-derived structural unit represented by the formula (B1-1).

From the same viewpoint, the polybutadiene having a 1,2-vinyl group is preferably a 1,2-polybutadiene homopolymer.

The preferable range of the 25° C. tensile elastic modulus of the component (B1) is the same as that of the 25° C. tensile elastic modulus of the component (B), but is preferably 0.005 to 0.5 GPa, more preferably 0.01 to 0.3 GPa, further preferably 0.03 to 0.1 GPa from the viewpoint of further improving the dielectric characteristics and the conductor adhesiveness of the obtained resin composition, and from the viewpoint of satisfactorily maintaining the heat resistance.

The number average molecular weight of the component (B1) is not particularly limited, but is preferably 400 to 3,000, more preferably 600 to 2,000, further preferably 800 to 1,500 from the viewpoint of compatibility with other resins, dielectric characteristics, conductor adhesiveness, and heat resistance.

[Modified Conjugated Diene Polymer (B2)]

The component (B) preferably contains the modified conjugated diene polymer (B2) as the polyolefin-based resin, and from the viewpoint of compatibility with other resins, dielectric characteristics, and conductor adhesion, it more preferably contains a modified conjugated diene polymer obtained by modifying (b1) a conjugated diene polymer having a vinyl group in the side chain [hereinafter, referred to as a “component (b1)” in some cases], with (b2) a maleimide compound having two or more N-substituted maleimide groups [hereinafter, referred to as a “component (b2)” in some cases].

The component (B2) may be used alone or in combination of two or more thereof.

As the component (b1), the conjugated diene polymer having a vinyl group in the side chain, which is described as the component (B1), can be used, and preferable embodiments are also the same.

The component (b1) may be used alone or in combination of two or more thereof.

The component (b2) is not particularly limited as long as it is a maleimide compound having two or more N-substituted maleimide groups.

The component (b2) may be used alone or in combination of two or more thereof.

The component (b2) is preferably the maleimide compound described as the maleimide compound (a1), which includes a fused ring of an aromatic ring and an aliphatic ring in the molecular structure thereof and has two or more N-substituted maleimide groups, from the viewpoint of compatibility with other resins, dielectric characteristics, and conductor adhesiveness. Preferred embodiments of the maleimide compound are the same as preferred embodiments of the maleimide compound (a1).

The component (b2) may be a maleimide compound [hereinafter, referred to as a “component (b2i)” in some cases] other than the maleimide compound (a1).

The component (b2i) is preferably a maleimide compound represented by the following formula (b2-1).

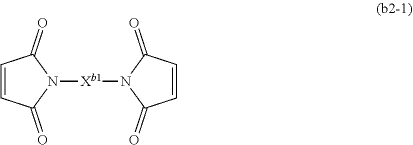

(In the formula, X^{b1} is a divalent organic group not containing a fused ring of an aromatic ring and an aliphatic ring.)

X^{b1} in the formula (b2-1) is a divalent organic group not containing a fused ring of an aromatic ring and an aliphatic ring, and corresponds to a divalent group obtained by removing two N-substituted maleimide groups from the component (b2i).

Examples of the divalent organic group represented by X^{b1} in the formula (b2-1) include a divalent group represented by the following formula (b2-2), a divalent group represented by the following formula (b2-3), a divalent group represented by the following formula (b2-4), a divalent group represented by the following formula (b2-5), and a divalent group represented by the following formula (b2-6).

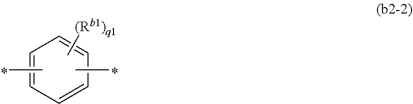

(In the formula, R^{b1} is an aliphatic hydrocarbon group having 1 to 5 carbon atoms or a halogen atom. q1 is an integer of 0 to 4. * represents a bonding site.)

Examples of the aliphatic hydrocarbon group having 1 to 5 carbon atoms and represented by R^{b1} in the formula (b2-2) include: alkyl groups having 1 to 5 carbon atoms such as a methyl group, an ethyl group, an n-propyl group, an isopropyl group, an n-butyl group, an isobutyl group, a t-butyl group, and an n-pentyl group; alkenyl groups having 2 to 5 carbon atoms, and alkynyl groups having 2 to 5 carbon atoms. The aliphatic hydrocarbon group having 1 to 5 carbon atoms may be either linear or branched. As the aliphatic hydrocarbon group having 1 to 5 carbon atoms, an aliphatic hydrocarbon group having 1 to 3 carbon atoms is preferable, an alkyl group having 1 to 3 carbon atoms is more preferable, and a methyl group is further preferable.

Examples of the halogen atom include a fluorine atom, a chlorine atom, a bromine atom, and an iodine atom.

q1 in the formula (b2-2) is an integer of 0 to 4, and from the viewpoint of availability, an integer of 0 to 2 is preferable, 0 or 1 is more preferable, and 0 is further preferable.

When q1 is an integer of 2 or more, R^{b1}'s may be the same or different.

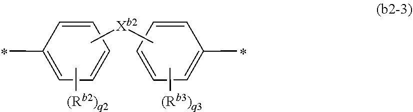

(In the formula, each of R^{b2} and R^{b3} is independently an aliphatic hydrocarbon group having 1 to 5 carbon atoms or a halogen atom. X^{b2} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent group represented by the following formula (b2-3-1). Each of q2 and q3 is independently an integer of 0 to 4. * represents a bonding site.)

Examples of the aliphatic hydrocarbon group having 1 to 5 carbon atoms and represented by R^{b2} and R^{b3} in the formula (b2-3) include: alkyl groups having 1 to 5 carbon atoms such as a methyl group, an ethyl group, an n-propyl group, an isopropyl group, an n-butyl group, an isobutyl group, a t-butyl group, and an n-pentyl group; alkenyl groups having 2 to 5 carbon atoms, and alkynyl groups having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, further preferably a methyl group or an ethyl group from the viewpoint of compatibility with other resins and suppression of gelation of a product during the reaction.

Examples of the halogen atom include a fluorine atom, a chlorine atom, a bromine atom, and an iodine atom.

Examples of the alkylene group having 1 to 5 carbon atoms and represented by X^{b2} in the formula (b2-3) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, further preferably a methylene group.

Examples of the alkylidene group having 2 to 5 carbon atoms and represented by X^{b2} in the formula (b2-3) include an ethylidene group, a propylidene group, an isopropylidene group, a butylidene group, an isobutylidene group, a pentylidene group, and an isopentylidene group. Among these, an alkylidene group having 2 to 4 carbon atoms is preferable, an alkylidene group having 2 or 3 carbon atoms is more preferable, and an isopropylidene group is further preferable.

Each of q2 and q3 in the formula (b2-3) is independently an integer of 0 to 4, and from the viewpoint of availability, compatibility with other resins, and suppression of gelation of a product during the reaction, each is preferably an integer of 1 to 3, more preferably 1 or 2, further preferably 2.

q2+q3 is preferably an integer of 1 to 8, more preferably an integer of 2 to 6, further preferably 4 from the viewpoint of availability, compatibility with other resins, and suppression of gelation of a product during the reaction.

When q2 or q3 is an integer of 2 or more, R^{b2}'s or R^{b3}'s may be the same or different.

The divalent group represented by the formula (b2-3-1), which is represented by X^{b2} in the formula (b2-3), is as follows.

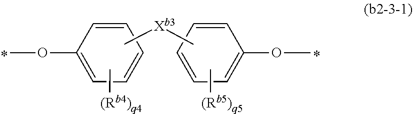

(In the formula, each of R^{b4} and R^{b5} is independently an aliphatic hydrocarbon group having 1 to 5 carbon atoms or a halogen atom. X^{b3} is an alkylene group having 1 to 5 carbon atoms, an alkylidene group having 2 to 5 carbon atoms, an ether group, a sulfide group, a sulfonyl group, a carbonyloxy group, a keto group or a single bond. Each of q4 and q5 is independently an integer of 0 to 4. * represents a bonding site.)

Examples of the aliphatic hydrocarbon group having 1 to 5 carbon atoms and represented by R^{b4} and R^{b5} in the formula (b2-3-1) include: alkyl groups having 1 to 5 carbon atoms such as a methyl group, an ethyl group, an n-propyl group, an isopropyl group, an n-butyl group, an isobutyl group, a t-butyl group, and an n-pentyl group; alkenyl groups having 2 to 5 carbon atoms, and alkynyl groups having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, further preferably a methyl group.

Examples of the halogen atom include a fluorine atom, a chlorine atom, a bromine atom, and an iodine atom.

Examples of the alkylene group having 1 to 5 carbon atoms and represented by X^{b3} in the formula (b2-3-1) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, further preferably a methylene group.

Examples of the alkylidene group having 2 to 5 carbon atoms and represented by X^{b3} in the formula (b2-3-1) include an ethylidene group, a propylidene group, an isopropylidene group, a butylidene group, an isobutylidene group, a pentylidene group, and an isopentylidene group. Among these, an alkylidene group having 2 to 4 carbon atoms is preferable, an alkylidene group having 2 or 3 carbon atoms is more preferable, and an isopropylidene group is further preferable.

As X^{b3} in the formula (b2-3-1), among the above options, an alkylidene group having 2 to 5 carbon atoms is preferable, an alkylidene group having 2 to 4 carbon atoms is more preferable, and an isopropylidene group is further preferable.

Each of q4 and q5 in the formula (b2-3-1) is independently an integer of 0 to 4, and from the viewpoint of availability, each is preferably an integer of 0 to 2, more preferably 0 or 1, further preferably 0.

When q4 or q5 is an integer of 2 or more, R^{b4}'s or R^{b5}'s may be the same or different.

As X^{b2} in the formula (b2-3), among the above options, an alkylene group having 1 to 5 carbon atoms, an alkylidene group having 2 to 5 carbon atoms, and a divalent group represented by the formula (b2-3-1) are preferable, an alkylene group having 1 to 5 carbon atoms is more preferable, and a methylene group is further preferable.

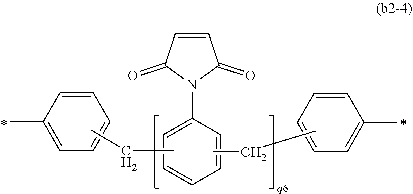

(In the formula, q6 is an integer of 0 to 10. * represents a bonding site.)

q6 in the formula (b2-4) is preferably an integer of 0 to 5, more preferably an integer of 0 to 4, further preferably an integer of 0 to 3 from the viewpoint of availability.

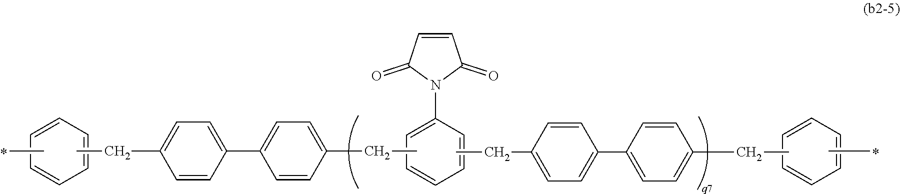

(In the formula, q7 is a number of 0 to 5. * represents a bonding site.)

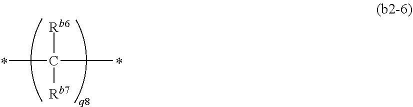

(In the formula, each of R^{b6} and R^{b7} is independently a hydrogen atom or an aliphatic hydrocarbon group having 1 to 5 carbon atoms. q8 is an integer of 1 to 8. * represents a bonding site.)

Examples of the aliphatic hydrocarbon group having 1 to 5 carbon atoms and represented by R^{b6} and R^{b7} in the formula (b2-6) include: alkyl groups having 1 to 5 carbon atoms such as a methyl group, an ethyl group, an n-propyl group, an isopropyl group, an n-butyl group, an isobutyl group, a t-butyl group, and an n-pentyl group; alkenyl groups having 2 to 5 carbon atoms, and alkynyl groups having 2 to 5 carbon atoms. The aliphatic hydrocarbon group having 1 to 5 carbon atoms may be either linear or branched.

q8 in the formula (b2-6) is an integer of 1 to 8, and is preferably an integer of 1 to 5, more preferably an integer of 1 to 3, further preferably 1. When q8 is an integer of 2 or more, R^{b6}'s or R^{b7}'s may be the same or different.

Examples of the component (b2i) include, an aromatic bismaleimide compound having two N-substituted maleimide groups bonded to an aromatic ring, an aromatic polymaleimide compound having three or more N-substituted maleimide groups bonded to an aromatic ring, and an aliphatic maleimide compound having an N-substituted maleimide group bonded to an aliphatic group.

Specific examples of the component (b2i) include N,N′-ethylenebismaleimide, N,N′-hexamethylenebismaleimide, N,N′-(1,3-phenylene)bismaleimide, N,N′-[1,3-(2-methylphenylene)]bismaleimide, N,N′-[1,3-(4-methylphenylene)]bismaleimide, N,N′-(1,4-phenylene)bismaleimide, bis(4-maleimidephenyl)methane, bis(3-methyl-4-maleimidephenyl)methane, bis(3-ethyl-5-methyl-4-maleimidephenyl)methane, bis(4-maleimidephenyl)ether, bis(4-maleimidephenyl)sulfone, bis(4-maleimidephenyl)sulfide, bis(4-maleimidephenyl)ketone, bis(4-maleimidecyclohexyl)methane, 1,4-bis(4-maleimidephenyl)cyclohexane, 1,4-bis(maleimidemethyl)cyclohexane, 1,4-bis(maleimidemethyl)benzene, 1,3-bis(4-maleimidephenoxy)benzene, 1,3-bis(3-maleimidephenoxy)benzene, bis[4-(3-maleimidephenoxy)phenyl]methane, bis[4-(4-maleimidephenoxy)phenyl]methane, 1,1-bis[4-(3-maleimidephenoxy)phenyl]ethane, 1,1-bis[4-(4-maleimidephenoxy)phenyl]ethane, 1,2-bis[4-(3-maleimidephenoxy)phenyl]ethane, 1,2-bis[4-(4-maleimidephenoxy)phenyl]ethane, 2,2-bis[4-(3-maleimidephenoxy)phenyl]propane, 2,2-bis[4-(4-maleimidephenoxy)phenyl]propane, 2,2-bis[4-(3-maleimidephenoxy)phenyl]butane, 2,2-bis[4-(4-maleimidephenoxy)phenyl]butane, 2,2-bis[4-(3-maleimidephenoxy)phenyl]-1,1,1,3,3,3-hexafluoropropane, 2,2-bis[4-(4-maleimidephenoxy)phenyl]-1,1,1,3,3,3-hexafluoropropane, 4,4-bis(3-maleimidephenoxy)biphenyl, 4,4-bis(4-maleimidephenoxy)biphenyl, bis[4-(3-maleimidephenoxy)phenyl]ketone, bis[4-(4-maleimidephenoxy)phenyl]ketone, bis(4-maleimidephenyl)disulfide, bis[4-(3-maleimidephenoxy)phenyl]sulfide, bis[4-(4-maleimidephenoxy)phenyl]sulfide, bis[4-(3-maleimidephenoxy)phenyl]sulfoxide, bis[4-(4-maleimidephenoxy)phenyl]sulfoxide, bis[4-(3-maleimidephenoxy)phenyl]sulfone, bis[4-(4-maleimidephenoxy)phenyl]sulfone, bis[4-(3-maleimidephenoxy)phenyl]ether, bis[4-(4-maleimidephenoxy)phenyl]ether, 1,4-bis[4-(4-maleimidephenoxy)-α,α-dimethylbenzyl]benzene, 1,3-bis[4-(4-maleimidephenoxy)-α,α-dimethylbenzyl]benzene, 1,4-bis[4-(3-maleimidephenoxy)-α,α-dimethylbenzyl]benzene, 1,3-bis[4-(3-maleimidephenoxy)-α,α-dimethylbenzyl]benzene, 1,4-bis[4-(4-maleimidephenoxy)-3,5-dimethyl-α,α-dimethylbenzyl]benzene, 1,3-bis[4-(4-maleimidephenoxy)-3,5-dimethyl-α,α-dimethylbenzyl]benzene, 1,4-bis[4-(3-maleimidephenoxy)-3,5-dimethyl-α,α-dimethylbenzyl]benzene, 1,3-bis[4-(3-maleimidephenoxy)-3,5-dimethyl-α,α-dimethylbenzyl]benzene, polyphenylmethanemaleimide, and biphenylaralkyl-type maleimide compounds.

The modified conjugated diene polymer (B2) preferably has, in a side chain thereof, a substituent [hereinafter sometimes referred to as “substituent (x)”.] formed by a reaction between the vinyl group of the conjugated diene polymer (b1) and the N-substituted maleimide group of the maleimide compound (b2).

From the viewpoint of compatibility with other resins, dielectric characteristics, low thermal expansion and heat resistance, the substituent (x) is preferably a group containing a structure represented by the following general formula (B2-11) or (B2-12) as a structure derived from the maleimide compound (b2).

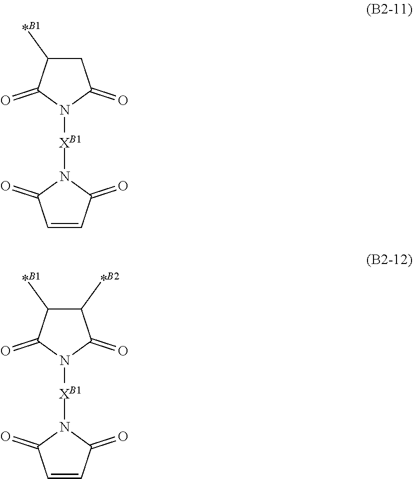

(In the formula, X^{B1} is a divalent group obtained by removing two N-substituted maleimide groups from the component (b2), and *^{B1} is a site that is bonded to a carbon atom derived from a vinyl group included in the side chain of the component (b1). *^{B2} is a site that is bonded to another atom.)

The modified conjugated diene polymer (B2) preferably has a substituent (x) and a vinyl group (y) in a side chain thereof.

The extent to which the substituent (x) is present in the modified conjugated diene polymer (B2) can be indicated by the extent to which the vinyl group of the component (b1) has been modified by the component (b2) [hereinafter sometimes referred to as “vinyl group modification rate”.].

The vinyl group modification rate is not particularly limited; however, it is preferably 20 to 70%, more preferably 30 to 60%, and still more preferably 35 to 50%, from the viewpoint of compatibility with other resins, dielectric characteristics, low thermal expansion and heat resistance. Here, the vinyl group modification rate is a value determined by a method described in the Examples.

The vinyl group (y) is preferably a 1,2-vinyl group of a structural unit derived from butadiene.

The preferable range of the 25° C. tensile elastic modulus of the component (B2) is the same as that of the 25° C. tensile elastic modulus of the component (B), but is preferably 0.01 to 1 GPa, more preferably 0.03 to 0.5 GPa, further preferably 0.05 to 0.15 GPa from the viewpoint of further improving the dielectric characteristics and the conductor adhesiveness of the obtained resin composition, and from the viewpoint of satisfactorily maintaining the heat resistance.

The number average molecular weight of the component (B2) is not particularly limited, but is preferably 700 to 6,000, more preferably 800 to 5,000, further preferably 1,000 to 2,500 from the viewpoint of compatibility with other resins, dielectric characteristics, low thermal expansion, and heat resistance.

The component (B2) can be produced by carrying out a reaction between the conjugated diene polymer (b1) and the maleimide compound (b2).

The method for carrying out the reaction between the conjugated diene polymer (b1) and the maleimide compound (b2) is not particularly limited. For example, the component (B2) can be obtained by charging the conjugated diene polymer (b1), the maleimide compound (b2), a reaction catalyst, and an organic solvent into a reaction vessel, and carrying out a reaction with heating, heat retention, stirring, etc. if necessary.

The reaction temperature for the above reaction is preferably 70 to 120° C., more preferably 80 to 110° C., further preferably 85 to 105° C. from the viewpoint of the workability and the gelation suppression of a product during the reaction.

The reaction time of the above reaction is preferably 0.5 to 15 h, more preferably 1 to 10 h, further preferably 3 to 7 h from the viewpoint of the productivity and sufficient progress of the reaction.

Meanwhile, these reaction conditions can be appropriately adjusted according to the types of raw materials to be used, and the like, and are not particularly limited.

Examples of the organic solvent used for the above reaction include: alcohol-based solvents such as methanol, ethanol, butanol, butylcellosolve, ethyleneglycolmonomethylether, and propyleneglycolmonomethylether; ketone-based solvents such as acetone, methylethylketone, methylisobutylketone, and cyclohexanone; aromatic hydrocarbon-based solvents such as toluene, xylene, and mesitylene; ester-based solvents such as methoxyethylacetate, ethoxyethylacetate, butoxyethylacetate, and ethyl acetate; and nitrogen atom-containing solvents such as N,N-dimethylformamide, N,N-dimethylacetamide, and N-methyl-2-pyrrolidone.

The organic solvent may be used alone or in combination of two or more thereof. Among these, toluene is preferable from the viewpoint of resin solubility.

When the above reaction is carried out in an organic solvent, the total content of the conjugated diene polymer (b1) and the maleimide compound (b2) in the reaction solution is not particularly limited, but is preferably 10 to 70% by mass, more preferably 15 to 60% by mass, further preferably 20 to 50% by mass. When the total content of the conjugated diene polymer (b1) and the maleimide compound (b2) is equal to or greater than the lower limit value, a good reaction rate is obtained, and the productivity tends to be better. Further, when the total content of the conjugated diene polymer (b1) and the maleimide compound (b2) is equal to or less than the upper limit value, a better solubility is obtained, and the stirring efficiency is improved, and thus the gelation of the product during the reaction tends to be further suppressed.

As the reaction catalyst, organic peroxide is preferable, and α,α′-bis(t-butylperoxy)diisopropylbenzene is more preferable from the viewpoint of obtaining sufficient reactivity while suppressing the gelation of the product during the reaction.

The reaction catalyst may be used alone or in combination of two or more thereof.

The use amount of the reaction catalyst is not particularly limited, but is preferably 0.01 to 1 parts by mass, more preferably 0.03 to 0.5 parts by mass, further preferably 0.05 to 0.2 parts by mass with respect to 100 parts by mass as the total amount of the conjugated diene polymer (b1) and the maleimide compound (b2) from the viewpoint of the reaction rate and the reaction uniformity.

When the above reaction is carried out, a ratio (Mₘ/Mᵥ) of the number of moles (Mₘ) of the N-substituted maleimide groups included in the maleimide compound (b2) to the number of moles (Mᵥ) of the side-chain vinyl groups included in the conjugated diene polymer (b1) is not particularly limited, but is preferably 0.001 to 0.5, more preferably 0.005 to 0.1, further preferably 0.008 to 0.05 from the viewpoint of the compatibility between the obtained component (B2) and other resins and suppression of gelation of a product during the reaction.

[Styrene-Based Elastomer (B3)]

The component (B) preferably contains the styrene-based elastomer (B3) as the polyolefin-based resin.

The component (B3) is not particularly limited as long as it is an elastomer having a 25° C. tensile elastic modulus of 10 GPa or less and having a structural unit derived from a styrene-based compound.

The component (B3) may be used alone or in combination of two or more thereof.

The component (B3) preferably has a structural unit derived from a styrene-based compound, which is represented by the following formula (B3-1).

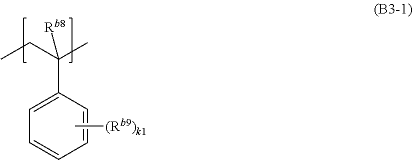

(In the formula, R^{b8} is a hydrogen atom or an alkyl group having 1 to 5 carbon atoms, and R^{b9} is an alkyl group having 1 to 5 carbon atoms. k is an integer of 0 to 5.)

Examples of the alkyl group having 1 to 5 carbon atoms and represented by R^{b8} and R^{b9} in the formula (B3-1) include a methyl group, an ethyl group, an n-propyl group, an isopropyl group, an n-butyl group, an isobutyl group, a t-butyl group, and an n-pentyl group. The alkyl group having 1 to 5 carbon atoms may be either linear or branched. Among these, an alkyl group having 1 to 3 carbon atoms is preferable, an alkyl group having 1 or 2 carbon atoms is more preferable, and a methyl group is further preferable.

k1 in the formula (B3-1) is an integer of 0 to 5, and is preferably an integer of 0 to 2, more preferably 0 or 1, further preferably 0.

Examples of a structural unit other than the structural units derived from a styrene-based compound of the component (B3) include a structural unit derived from butadiene, a structural unit derived from isoprene, a structural unit derived from maleic acid, and a structural unit derived from maleic anhydride.

The structural unit derived from butadiene and the structural unit derived from isoprene may be hydrogenated. When hydrogenated, the structural unit derived from butadiene becomes a structural unit in which an ethylene unit and a butylene unit are mixed, and the structural unit derived from isoprene becomes a structural unit in which an ethylene unit and a propylene unit are mixed.

From the viewpoint of dielectric characteristics, adhesion to a conductor, heat resistance, glass transition temperature and low thermal expansion, the component (B3) is preferably one or more selected from the group consisting of a hydrogenated styrene-butadiene-styrene block copolymer (SEBS, SBBS), a hydrogenated styrene-isoprene-styrene block copolymer (SEPS), and a styrene-maleic anhydride copolymer (SMA), more preferably one or more selected from the group consisting of a hydrogenated styrene-butadiene-styrene block copolymer (SEBS) and a hydrogenated styrene-isoprene-styrene block copolymer (SEPS), and still more preferably a hydrogenated styrene-butadiene-styrene block copolymer (SEBS).

In the SEBS, the content of styrene-derived structural units [hereinafter, referred to as a “styrene content” in some cases] is not particularly limited, but is preferably 5 to 60% by mass, more preferably 7 to 40% by mass, further preferably 10 to 20% by mass from the viewpoint of dielectric characteristics, conductor adhesiveness, heat resistance, glass transition temperature and low thermal expansion.

The melt flow rate (MFR) of SEBS is not particularly limited, but is preferably 0.1 to 20 g/10 min, more preferably 1 to 10 g/10 min, further preferably 3 to 7 g/10 min under measurement conditions of 230° C. and a load of 2.16 kgf (21.2 N) from the viewpoint of easily adjusting the 25° C. tensile elastic modulus of the component (B3) to a suitable range.

Examples of commercially available products of SEBS include Tuftec (registered trademark) H series and M series manufactured by Asahi Kasei Corporation, Septon (registered trademark) series manufactured by Kuraray Co., Ltd., and Kraton (registered trademark) G polymer series manufactured by Kraton Polymer Japan Co., Ltd.

The preferable range of the 25° C. tensile elastic modulus of the component (B3) is the same as that of the 25° C. tensile elastic modulus of the component (B), but is preferably 0.02 to 4 GPa, more preferably 0.05 to 2 GPa, further preferably 0.1 to 1 GPa from the viewpoint of further improving the dielectric characteristics and the conductor adhesiveness of the obtained resin composition, and from the viewpoint of satisfactorily maintaining the heat resistance.

The number average molecular weight of the component (B3) is not particularly limited, but is preferably 10,000 to 500,000, more preferably 50,000 to 350,000, further preferably 100,000 to 200,000 from the viewpoint of easily adjusting the 25° C. tensile elastic modulus of the component (B3) to a suitable range.

In the total amount of the component (B), the content of at least one selected from the group consisting of the component (B1), the component (B2) and the component (B3) is not particularly limited, but is preferably 60% by mass or more, more preferably 80% by mass or more, further preferably 90% by mass or more from the viewpoint of dielectric characteristics and conductor adhesiveness. In the total amount of the component (B), the content of at least one selected from the group consisting of the component (B1), the component (B2) and the component (B3) is not particularly limited, but may be 100% by mass or less, may be 98% by mass or less, or may be 95% by mass or less.

The component (B) preferably contains the component (B2) and the component (B3) as the polyolefin-based resin from the viewpoint of dielectric characteristics and conductor adhesiveness.

When the polyolefin-based resin contains the component (B2) and the component (B3), the content ratio of the component (B2) to the component (B3) [component (B2)/component (B3)] is not particularly limited, but is preferably 0.1 to 10, more preferably 0.2 to 5, further preferably 0.5 to 1 from the viewpoint of compatibility, dielectric characteristics, and conductor adhesiveness.

As for the component (B), a polyphenylene ether-based resin (B4) [hereinafter, referred to as a “component (B4)” in some cases], a silicon-based resin (B5) [hereinafter, referred to as a “component (B5)” in some cases], and an epoxy resin (B6) [hereinafter, referred to as a “component (B6)” in some cases] are also preferable.

(Polyphenylene Ether-Based Resin (B4))

The component (B4) is not particularly limited as long as it is a polyphenylene ether-based resin having a 25° C. tensile elastic modulus of 10 GPa or less.

In the present specification, the concept of a phenylene group included in the “polyphenylene ether” includes not only an unsubstituted phenylene group, but also a phenylene group substituted with a substituent.

The component (B4) may be used alone or in combination of two or more thereof.

The component (B4) also has at least a phenylene ether bond, and preferably has a structural unit represented by the following formula (B4-1).

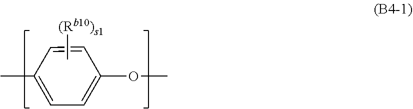

(In the formula, R^{b10} is an aliphatic hydrocarbon group having 1 to 5 carbon atoms or a halogen atom. s1 is an integer of 0 to 4.)

Examples of the aliphatic hydrocarbon group having 1 to 5 carbon atoms and represented by R^{b10} in the formula (B4-1) include alkyl groups having 1 to 5 carbon atoms such as a methyl group, an ethyl group, an n-propyl group, an isopropyl group, an n-butyl group, an isobutyl group, a t-butyl group, and an n-pentyl group; alkenyl groups having 2 to 5 carbon atoms, and alkynyl groups having 2 to 5 carbon atoms. The aliphatic hydrocarbon group having 1 to 5 carbon atoms may be either linear or branched. As the aliphatic hydrocarbon group having 1 to 5 carbon atoms, an aliphatic hydrocarbon group having 1 to 3 carbon atoms is preferable, a methyl group and an ethyl group are more preferable, and a methyl group is further preferable.

Examples of the halogen atom include a fluorine atom, a chlorine atom, a bromine atom, and an iodine atom.

s1 in the formula (B4-1) is an integer of 0 to 4, preferably an integer of 0 to 2, more preferably 1 or 2, further preferably 2. When s1 is an integer of 2 or more, R^{b10}'s may be the same or different.

When s1 is 1 or 2, it is preferable that R^{b10} is substituted at the ortho position on the benzene ring (meanwhile, based on the substitution position of the oxygen atom).

The structural unit represented by the formula (B4-1) is preferably a structural unit represented by the following formula (B4-2).

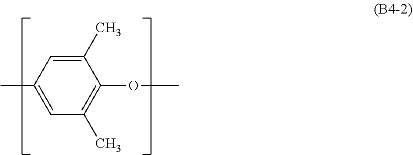

The component (B4) may have a structural unit other than a phenylene ether unit, but may not have a structural unit other than a phenylene ether unit.

The component (B4) may have phenolic hydroxy groups at one end or both ends. The average number of phenolic hydroxy groups per molecule included in the component (B4) is preferably 1 to 2, more preferably 1.4 to 1.9, further preferably 1.6 to 1.85.

The 25° C. tensile elastic modulus of the component (B4) is preferably 0.5 to 7 GPa, more preferably 1 to 5 GPa, further preferably 1.5 to 3 GPa from the viewpoint of improving the dielectric characteristics and the conductor adhesiveness of the obtained resin composition, from the viewpoint of satisfactorily maintaining the heat resistance and from the viewpoint of availability.

The number average molecular weight of the component (B4) is not particularly limited, but is preferably 1,000 to 50,000, more preferably 5,000 to 20,000, further preferably 8,000 to 15,000 from the viewpoint of easily adjusting the 25° C. tensile elastic modulus of the component (B4) to a suitable range.

(Silicon-Based Resin (B5))

The component (B5) is not particularly limited as long as it is a silicon-based resin having a 25° C. tensile elastic modulus of 10 GPa or less.

The component (B5) may be used alone or in combination of two or more thereof.

The component (B5) has at least a siloxane bond, and preferably has a structural unit represented by the following formula (B5-1).

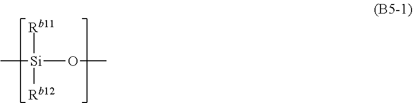

(In the formula, each of R^{b11} and R^{b12} is independently an alkyl group having 1 to 5 carbon atoms, a phenyl group or a phenyl group having a substituent.)

Examples of the alkyl group having 1 to 5 carbon atoms and represented by R^{b11} and R^{b12} in the formula (B5-1) include a methyl group, an ethyl group, an n-propyl group, an isopropyl group, an n-butyl group, an isobutyl group, a t-butyl group, and an n-pentyl group. The alkyl group having 1 to 5 carbon atoms may be either linear or branched. As the alkyl group, an alkyl group having 1 to 3 carbon atoms is preferable, a methyl group and an ethyl group are more preferable, and a methyl group is further preferable.

In the phenyl group having a substituent and represented by R^{b11} and R^{b12} in the formula (B5-1), examples of the substituent included in the phenyl group include an alkyl group having 1 to 5 carbon atoms, an alkenyl group having 2 to 5 carbon atoms, and an alkynyl group having 2 to 5 carbon atoms. Examples of the alkyl group having 1 to 5 carbon atoms include a methyl group, an ethyl group, an n-propyl group, an isopropyl group, an n-butyl group, an isobutyl group, a t-butyl group, and an n-pentyl group. Examples of the alkenyl group having 2 to 5 carbon atoms include a vinyl group, and an allyl group. Examples of the alkynyl group having 2 to 5 carbon atoms include an ethynyl group and a propargyl group. The alkyl group having 1 to 5 carbon atoms, the alkenyl group having 2 to 5 carbon atoms, and the alkynyl group having 2 to 5 carbon atoms may be either linear or branched.

Each of R^{b11} and R¹² in the formula (B5-1) is preferably an alkyl group having 1 to 5 carbon atoms, more preferably a methyl group or an ethyl group, further preferably a methyl group.

That is, the structural unit represented by the formula (B5-1) is preferably a dimethylsiloxane unit.

The component (B5) may be a linear silicon-based resin, or a branched silicon-based resin, but is preferably a linear silicon-based resin.

The component (B5) may have a reactive group in its molecular structure. The reactive group may be introduced into a part of the side chain of polysiloxane, or may be introduced into one end or both ends of polysiloxane. Further, the reactive groups may be introduced into one end or both ends as well as the side chain of polysiloxane.

Examples of the reactive group include an epoxy group, an amino group, a vinyl group, a hydroxy group, a methacryl group, a mercapto group, a carboxy group, an alkoxy group, and a silanol group. The component (B5) may contain one type or two or more types among the reactive groups.

Among these, an amino group and a vinyl group are preferable as for the reactive group. The amino group is preferably a primary amino group, or a secondary amino group, more preferably a primary amino group.

When the component (B5) has an amino group, from the viewpoint of compatibility with other resins, the component (B5) preferably has one or two primary amino groups, more preferably has two primary amino groups, and is further preferably diaminopolysiloxane having one primary amino group at each of two ends.

The preferable range of the 25° C. tensile elastic modulus of the component (B5) is the same as that of the 25° C. tensile elastic modulus of the component (B), but is preferably 0.01 to 1 GPa, more preferably 0.03 to 0.5 GPa, further preferably 0.05 to 0.15 GPa from the viewpoint of further improving the dielectric characteristics and the conductor adhesiveness of the obtained resin composition, and from the viewpoint of satisfactorily maintaining the heat resistance.

When the component (B5) has a reactive group, the equivalent of the reactive groups is not particularly limited, but is preferably 200 to 3,000 g/mol, more preferably 300 to 1,000 g/mol, further preferably 400 to 600 g/mol.

(Epoxy Resin (B6))

The component (B6) is not particularly limited as long as it is an epoxy resin having a 25° C. tensile elastic modulus of 10 GPa or less.

The component (B6) may be used alone or in combination of two or more thereof.

The component (B6) is preferably, for example, an epoxy resin having two or more epoxy groups. Epoxy resins are classified into glycidylether-type epoxy resins, glycidylamine-type epoxy resins, glycidylester-type epoxy resins and the like. Among these, glycidylether-type epoxy resins are preferable.

Examples of the component (B6) include an aliphatic chain-like epoxy resin, a rubber-modified epoxy resin, and an epoxy resin having an alicyclic skeleton.

Among these, an epoxy resin having an alicyclic skeleton is preferable from the viewpoint of improving the dielectric characteristics and the conductor adhesiveness of the obtained resin composition.

The alicyclic skeleton included in the component (B6) is not particularly limited, but is preferably an alicyclic skeleton having 5 to 20 ring carbon atoms, further preferably an alicyclic skeleton having 6 to 18 ring carbon atoms, particularly preferably an alicyclic skeleton having 8 to 14 ring carbon atoms.

Further, the alicyclic skeleton is preferably composed of two or more rings, more preferably of two to four rings, further preferably of three rings. Examples of the alicyclic skeleton composed of two or more rings include a norbornane skeleton, a decalin skeleton, a bicycloundecane skeleton, and a dicyclopentadiene skeleton.

As the alicyclic skeleton, a dicyclopentadiene skeleton is preferable.

Examples of the epoxy resin having an alicyclic skeleton include an epoxy resin represented by the following formula (B6-1).

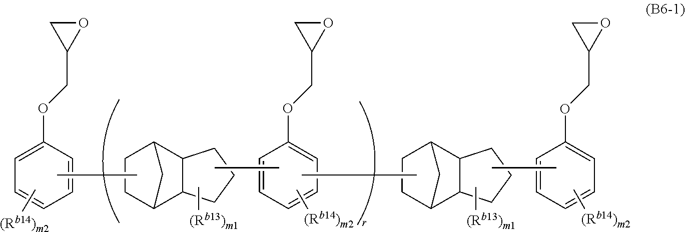

(In the formula, R^{b13} is an alkyl group having 1 to 12 carbon atoms, and may be substituted anywhere in the alicyclic skeleton. R^{b14} is an alkyl group having 1 to 12 carbon atoms. m1 is an integer of 0 to 6, and m2 is an integer of 0 to 3. r is a number of 0 to 10.)

Examples of the alkyl group having 1 to 12 carbon atoms and represented by R^{b13} in the formula (B6-1) include a methyl group, an ethyl group, a propyl group, a butyl group, a pentyl group, a hexyl group, a heptyl group, an octyl group, a nonyl group, and a decyl group. These alkyl groups may be either linear or branched. The alkyl group is preferably an alkyl group having 1 to 6 carbon atoms, more preferably an alkyl group having 1 to 3 carbon atoms, further preferably a methyl group.

m1 in the formula (B6-1) is an integer of 0 to 6, preferably an integer of 0 to 5, more preferably an integer of 0 to 2, further preferably 0.

When m1 is an integer of 2 or more, R^{b}i3's may be the same or different. Furthermore, R^{b13}'s may be substituted on the same carbon atom as far as possible or may be substituted on different carbon atoms.

Examples of the alkyl group having 1 to 12 carbon atoms and represented by R^{b14} in the formula (B6-1) include a methyl group, an ethyl group, a propyl group, a butyl group, a pentyl group, a hexyl group, a heptyl group, an octyl group, a nonyl group, and a decyl group. These alkyl groups may be either linear or branched. The alkyl group is preferably an alkyl group having 1 to 6 carbon atoms, more preferably an alkyl group having 1 to 3 carbon atoms, further preferably a methyl group.

m2 in the formula (B6-1) is an integer of 0 to 3, preferably 0 or 1, more preferably 0.

When m2 is an integer of 2 or more, R^{b141}s may be the same or different.

r in the formula (B6-1) represents the number of repetitions of the structural unit within round brackets, and is a number of 0 to 10, preferably 2 to 10. When the epoxy resin represented by the formula (B6-1) is a mixture of those having different numbers of repetitions of the structural unit within round brackets, r is expressed as the average value of the mixture.

The 25° C. tensile elastic modulus of the component (B6) is preferably 1 to 7 GPa, more preferably 1.5 to 5 GPa, further preferably 2 to 3 GPa from the viewpoint of improving the dielectric characteristics and the conductor adhesiveness of the obtained resin composition, from the viewpoint of satisfactorily maintaining the heat resistance, and from the viewpoint of availability.

The equivalent of epoxy groups of the component (B6) is not particularly limited, but is preferably 150 to 1,000 g/mol, more preferably 200 to 500 g/mol, further preferably 250 to 300 g/mol.

(Other Components (B))

Examples of components (B) other than the above include at least one selected from the group consisting of a polyurethane-based resin, a polyester-based resin, a polyamide-based resin and a polyacrylic-based resin.

Examples of the polyurethane-based resin include those having a hard segment composed of a low-molecular-weight diol and diisocyanate and a soft segment composed of a high-molecular-weight diol and diisocyanate.

Examples of the low-molecular-weight diol include ethyleneglycol, propyleneglycol, 1,4-butanediol, and bisphenol A. Examples of the high-molecular-weight diol include polypropyleneglycol, polytetramethyleneoxide, poly(1,4-butyleneadipate), poly(ethylene-1,4-butyleneadipate), polycaprolactone, poly(1,6-hexylenecarbonate), and poly(1,6-hexylene-neopentyleneadipate). Each of the low-molecular-weight diol and the high-molecular-weight diol may be used alone or in combination of two or more thereof.

The polyurethane-based resin may be used alone or in combination of two or more thereof.

Examples of the polyester-based resin include those obtained through polycondensation of dicarboxylic acids or derivatives thereof and diol compounds or derivatives thereof.

Examples of the dicarboxylic acid include: aromatic dicarboxylic acids such as terephthalic acid, isophthalic acid, and naphthalene dicarboxylic acid; aromatic dicarboxylic acids in which the hydrogen atom of the aromatic nucleus in the aromatic dicarboxylic acid is substituted with a methyl group, an ethyl group, a phenyl group or the like; aliphatic dicarboxylic acids having 2 to 20 carbon atoms such as adipic acid, sebacic acid, and dodecane dicarboxylic acid; and alicyclic dicarboxylic acids such as cyclohexane dicarboxylic acid. These dicarboxylic acids may be used alone or in combination of two or more thereof.

Examples of the diol compound include: aliphatic diols such as ethyleneglycol, 1,3-propanediol, 1,4-butanediol, 1,6-hexanediol, and 1,10-decanediol; alicyclic diols such as 1,4-cyclohexanediol; and aromatic diols such as bisphenol A, bis(4-hydroxyphenyl)methane, bis(4-hydroxy-3-methylphenyl)propane, and resorcin. These diol compounds may be used alone or in combination of two or more thereof.

Further, a multi-block copolymer may be used in which an aromatic polyester portion such as polybutyleneterephthalate is a hard segment component, and an aliphatic polyester portion such as polytetramethyleneglycol is a soft segment component.

The polyester-based resin may be used alone or in combination of two or more thereof.

As for the polyamide-based resin, a block copolymer may be exemplified in which a hard segment component is polyamide, and a soft segment component is poly butadiene, butadiene-acrylonitrile copolymer, styrene-butadiene copolymer, polyisoprene, ethylenepropylene copolymer, polyether, polyester, polybutadiene, polycarbonate, polyacrylate, polymethacrylate, polyurethane, silicon rubber or the like.

The polyamide-based resin may be used alone or in combination of two or more thereof.

Examples of the acrylic-based resin include a polymer obtained by polymerizing raw material monomers whose main component is acrylic acid ester. Examples of the acrylic acid ester include ethylacrylate, butylacrylate, methoxyethylacrylate, and ethoxyethylacrylate. Further, for a cross-linking point monomer, glycidylmethacrylate, allylglycidylether or the like may be used as a raw material, and acrylonitrile, ethylene, or the like may be copolymerized. Specific examples thereof include an acrylonitrile-butylacrylate copolymer, an acrylonitrile-butylacrylate-ethylacrylate copolymer, and an acrylonitrile-butylacrylate-glycidylmethacrylate copolymer.

The acrylic-based resin may be used alone or in combination of two or more thereof.

<Contents of Component (A) and Component (B), and Content Ratio Thereof>

In the resin composition of the present embodiment, the content of the component (A) is not particularly limited, but is preferably 10 to 90 parts by mass, more preferably 20 to 80 parts by mass, further preferably 25 to 75 parts by mass with respect to 100 parts by mass as the total of resin components in the resin composition of the present embodiment. When the content of the component (A) is equal to or greater than the lower limit value, the heat resistance, the moldability, the processability, the flame retardancy and the conductor adhesiveness tend to be further improved. Further, when the content of the component (A) is equal to or less than the upper limit value, the dielectric characteristics tend to be further improved.

Furthermore, the content of the component (A) is not particularly limited, but may be 30 parts by mass or more, may be 40 parts by mass or more, or may be 50 parts by mass or more with respect to 100 parts by mass as the total of resin components in the resin composition of the present embodiment, from the viewpoint of further improving the heat resistance, etc.

Further, the content of the component (A) is not particularly limited, but may be 70 parts by mass or less, may be 60 parts by mass or less, may be 50 parts by mass or less, or may be 40 parts by mass or less with respect to 100 parts by mass as the total of resin components in the resin composition of the present embodiment, from the viewpoint of further improving dielectric characteristics, etc.

Here, in the present specification, the “resin component” means a resin and a compound that forms a resin by a curing reaction. For example, the component (A) and the component (B) correspond to the resin components. Further, when the resin composition of the present embodiment contains, as an optional component, a resin or a compound that forms a resin by a curing reaction, in addition to the component (A) and the component (B), this optional component is also included in the resin components. The components (C), (D) and (E) to described below shall not be included in the resin components.

In the resin composition of the present embodiment, the content of the component (B) is not particularly limited, but is preferably 10 to 90 parts by mass, more preferably 20 to 80 parts by mass, further preferably 25 to 75 parts by mass with respect to 100 parts by mass as the total of resin components in the resin composition of the present embodiment. When the content of the component (B) is equal to or greater than the lower limit value, the dielectric characteristics tend to be further improved. Further, when the content of the component (B) is equal to or less than the upper limit value, the heat resistance, the moldability, the processability, the flame retardancy and the conductor adhesiveness tend to be further improved.

Furthermore, the content of the component (B) is not particularly limited but may be 30 parts by mass or more, may be 40 parts by mass or more, or may be 50 parts by mass or more with respect to 100 parts by mass as the total of resin components in the resin composition of the present embodiment from the viewpoint of further improving the dielectric characteristics or the like.

Further, the content of the component (B) is not particularly limited, but may be 70 parts by mass or less, may be 60 parts by mass or less, may be 50 parts by mass or less, or may be 40 parts by mass or less with respect to 100 parts by mass as the total of resin components in the resin composition of the present embodiment, from the viewpoint of further improving the heat resistance, etc.

In the resin composition of the present embodiment, the content ratio of the component (A) to the component (B) [(A)/(B)] is not particularly limited, but is preferably 0.1 to 9, more preferably 0.25 to 4, further preferably 0.3 to 3 on a mass basis. When the content ratio [(A)/(B)] of the component (A) to the component (B) is equal to or greater than the lower limit value, the heat resistance, the moldability, the processability, the flame retardancy and the conductor adhesiveness tend to be further improved. Further, when the content ratio [(A)/(B)] of the component (A) to the component (B) is equal to or less than the upper limit value, the dielectric characteristics tend to be further improved.

Furthermore, the content ratio [(A)/(B)] of the component (A) to the component (B) is not particularly limited, but may be 0.5 or more, may be 1 or more, or may be 1.5 or more on a mass basis from the viewpoint of further improving the heat resistance, etc.

Further, the content ratio [(A)/(B)] of the component (A) to the component (B) is not particularly limited, but may be 7 or less, may be 2 or less, may be 1 or less, or may be 0.6 or less on a mass basis from the viewpoint of further improving the dielectric characteristics, etc.

In the resin composition of the present embodiment, the content of the resin components is not particularly limited, but is preferably 10 to 70% by mass, more preferably 20 to 65% by mass, further preferably 30 to 60% by mass from the viewpoint of low thermal expansion, elastic modulus, heat resistance, flame retardancy and conductor adhesiveness.

<Other Components>

The resin composition of the present embodiment may be formed further containing other components depending on desired performance.

Examples of the other components include one or more selected from the group consisting of an inorganic filler (C) [hereinafter sometimes referred to as “component (C)”.], a flame retardant (D) [hereinbelow sometimes referred to as “component (D)”.], and a curing accelerator (E) [hereinafter sometimes referred to as “component (E)”.].

However, depending on desired performance, the resin composition of the present embodiment may not contain one or more selected from the group consisting of an inorganic filler (C), a flame retardant (D), and a curing accelerator (E).

These components are described in detail below.

(Inorganic Filler (C))

By containing the inorganic filler (C) in the resin composition of the present embodiment, low thermal expansion, elastic modulus, heat resistance and flame retardancy tend to be further improved.

The inorganic filler (C) may be used alone or in combination of two or more thereof.

Examples of the inorganic filler (C) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Of these, silica, alumina, mica, and talc are preferred, silica and alumina are more preferred, and silica is even more preferred, from the viewpoints of low thermal expansion, elastic modulus, heat resistance, and flame retardancy.

Examples of silica include precipitated silica that is produced by a wet method and has a high water content, and dry-process silica that is produced by a dry method and contains almost no bound water. Further, examples of the dry-process silica include crushed silica, fumed silica, and fused silica, depending on the difference in production methods.

The average particle size of the inorganic filler (C) is not particularly limited, but is preferably 0.01 to 20 μm, more preferably 0.1 to 10 μm, further preferably 0.2 to 1 μm, particularly preferably 0.3 to 0.8 μm from the viewpoint of dispersibility and fine wiring.

In the present specification, the average particle size of the inorganic filler (C) refers to a particle diameter at a point corresponding to a volume of 50% based on a total volume of the particles as 100% when the cumulative frequency distribution curve of the particle diameter is obtained. The particle size of the inorganic filler (C) can be measured by, for example, a particle size distribution measuring device or the like using a laser diffraction scattering method.

As the shape of the inorganic filler (C), for example, a spherical shape, a crushed shape, etc. may be exemplified, and a spherical shape is preferable.

When the resin composition of the present embodiment contains an inorganic filler (C), although the content of the inorganic filler (C) in the resin composition is not particularly limited, from the viewpoint of low thermal expansion, elastic modulus, heat resistance and flame retardancy, it is preferably 10 to 70% by mass, more preferably 20 to 65% by mass, and further preferably 30 to 60% by mass, based on a total solid content (100% by mass) of the resin composition.

When the resin composition of the present embodiment contains the inorganic filler (C), a coupling agent may be used for the purpose of improving the dispersibility of the inorganic filler (C) and the adhesion to an organic component. Examples of the coupling agent include a silane coupling agent and a titanate coupling agent. Among these, a silane coupling agent is preferable. Examples of the silane coupling agent include an aminosilane coupling agent, a vinylsilane coupling agent, and an epoxysilane coupling agent.

When a coupling agent is used in the resin composition of the present embodiment, a surface treatment method for the inorganic filler (C) may be an integral blend treatment method in which the coupling agent is added after the inorganic filler (C) is blended in the resin composition, or may be a method of previously subjecting the inorganic filler (C) to a surface treatment with the coupling agent in a dry or wet mode. Of these, the method of previously subjecting the inorganic filler (C) to a surface treatment with the coupling agent in a dry or wet mode is preferable from the viewpoint of more effectively revealing the advantages of the inorganic filler (C).

For the purpose of improving dispersibility in the resin composition, the inorganic filler (C) may be made into a state of slurry in which it is previously dispersed in an organic solvent and then mixed with other components.

(Flame Retardant (D))

By containing the flame retardant (D) in the resin composition of the present embodiment, the flame retardancy of the resin composition tends to be further improved.

The flame retardant (D) may be used alone or in combination of two or more thereof.

Further, the resin composition of the present embodiment may contain a frame retardant auxiliary agent as necessary.

Examples of the flame retardant (D) include a phosphorus-based flame retardant, a metal hydrate, and a halogen-based flame retardant, and from the viewpoint of environmental problems, a phosphorus-based flame retardant and a metal hydrate are preferred.

—Phosphorus-Based Flame Retardant—

The phosphorus-based flame retardant is not particularly limited as long as it contains a phosphorus atom among those commonly used as flame retardants, and may be an inorganic phosphorus-based flame retardant or an organic phosphorus-based flame retardant. From the viewpoint of environmental problems, the phosphorus-based flame retardant preferably does not contain a halogen atom.

Examples of the inorganic phosphorus-based flame retardant include red phosphorus; ammonium phosphates, such as monoammonium phosphate, diammonium phosphate, triammonium phosphate and ammonium polyphosphate; inorganic nitrogen-containing phosphorus compounds, such as phosphate amide; phosphoric acid; and phosphine oxide.

Examples of the organic phosphorus-based flame retardant include aromatic phosphoric acid esters, monosubstituted phosphonic acid diesters, disubstituted phosphinic acid esters, metal salts of disubstituted phosphinic acids, organic nitrogen-containing phosphorus compounds, and cyclic organic phosphorus compounds. Of these, aromatic phosphoric acid ester compounds and metal salts of disubstituted phosphinic acids are preferred. Here, examples of metal salts include lithium salts, sodium salts, potassium salts, calcium salts, magnesium salts, aluminum salts, titanium salts, and zinc salts. Of these, aluminum salts are preferred. In addition, among the organic phosphorus-based flame retardants, aromatic phosphoric acid esters are preferred.

Examples of the aromatic phosphoric acid esters include triphenyl phosphate, tricresyl phosphate, trixylenyl phosphate, cresyl diphenyl phosphate, cresyl di-2,6-xylenyl phosphate, resorcinol bis(diphenyl phosphate), 1,3-phenylene bis(di-2,6-xylenyl phosphate), bisphenol A-bis(diphenyl phosphate), and 1,3-phenylene bis(diphenyl phosphate).

Examples of the monosubstituted phosphonic acid diesters include divinyl phenylphosphonate, diallyl phenylphosphonate, and bis(1-butenyl) phenylphosphonate.

Examples of the disubstituted phosphinic acid esters include phenyl diphenylphosphinate and methyl diphenylphosphinate.

Examples of the metal salts of disubstituted phosphinic acids include metal salts of dialkylphosphinic acid, metal salts of diallylphosphinic acid, metal salts of divinylphosphinic acid, and metal salts of diarylphosphinic acid. Aluminum salts are preferred as these metal salts.

Examples of the organic nitrogen-containing phosphorus compounds include phosphazene compounds, such as bis(2-allylphenoxy)phosphazene and dicresylphosphazene; melamine phosphate; melamine pyrophosphate; melamine polyphosphate; and melam polyphosphate.

Examples of the cyclic organic phosphorus compounds include 9,10-dihydro-9-oxa-10-phosphaphenanthrene-10-oxide, and 10-(2,5-dihydroxyphenyl)-9,10-dihydro-9-oxa-10-phosphaphenanthrene-10-oxide.

Among the organic phosphorus-based flame retardants, the aromatic phosphoric acid esters and the metal salts of disubstituted phosphinic acids are preferred, 1,3-phenylenebis(di-2,6-xylenyl phosphate) and aluminum salts of dialkylphosphinic acids are more preferred, and aluminum tris-diethylphosphinate is even more preferred.

—Metal Hydrate—

Examples of the metal hydrate include an aluminum hydroxide hydrate and a magnesium hydroxide hydrate.

—Halogen-Based Flame Retardant—

Examples of the halogen-based flame retardant include a chlorine-based flame retardant and a bromine-based flame retardant. Examples of the chlorine-based flame retardant include a chlorinated paraffin.

When the resin composition of the present embodiment contains the flame retardant (D), although the content of the flame retardant (D) is not particularly limited, it is preferably 1 to 15 parts by mass, more preferably 4 to 12 parts by mass, and even more preferably 6 to 10 parts by mass, based on 100 parts by mass of the total resin components in the resin composition. When the content of the flame retardant (D) is equal to or more than the aforementioned lower limit, flame retardancy tends to be further improved. Moreover, when the content of the flame retardant (D) is equal to or less than the aforementioned upper limit, moldability, adhesion to a conductor, heat resistance, and glass transition temperature tend to be further improved.

Examples of the frame retardant auxiliary agent include inorganic frame retardant auxiliary agents such as antimony trioxide, and zinc molybdate.

When the resin composition of the present embodiment contains a frame retardant auxiliary agent, the content is not particularly limited, but is preferably 0.01 to 20 parts by mass, more preferably 0.05 to 10 parts by mass, further preferably 0.1 to 5 parts by mass with respect to 100 parts by mass as the total of resin components in the resin composition of the present embodiment. When the content of the frame retardant auxiliary agent falls within the above range, a better chemical resistance tends to be obtained.

(Curing Accelerator (E))

By containing the curing accelerator (E), curability of the resin composition of the present embodiment is improved, and dielectric characteristics, heat resistance, adhesion to a conductor, elastic modulus, and glass transition temperature tend to be better.

The curing accelerator (E) may be used alone or in combination of two or more thereof.

Examples of the curing accelerator (E) include an acidic catalyst, such as p-toluenesulfonic acid; an amine compound, such as triethylamine, pyridine and tributylamine; an imidazole compound, such as methylimidazole and phenylimidazole; an isocyanate-masked imidazole compound, such as an addition reaction product of a hexamethylene diisocyanate resin and 2-ethyl-4-methylimidazole; a tertiary amine compound; a quaternary ammonium compound; a phosphorus-based compound such as triphenylphosphine; an organic peroxide, such as dicumyl peroxide, 2,5-dimethyl-2,5-bis(t-butylperoxy)hexyne-3,2,5-dimethyl-2,5-bis(t-butylperoxy)hexane, t-butylperoxyisopropyl monocarbonate, and α,α′-bis(t-butylperoxy)diisopropylbenzene; and carboxylate of manganese, cobalt, zinc, etc.

Of these, from the viewpoint of heat resistance, glass transition temperature and storage stability, an imidazole compound, an isocyanate-masked imidazole compound, an organic peroxide and a carboxylate are preferred, an organic peroxide is more preferred, and dicumyl peroxide is still more preferred.

When the resin composition of the present embodiment contains the curing accelerator (E), although the content of the curing accelerator (E) is not particularly limited, it is preferably 0.01 to 10 parts by mass, more preferably 0.1 to 7 parts by mass, further preferably 0.5 to 5 parts by mass, based on 100 parts by mass of the total resin components in the resin composition of the present embodiment. When the content of the curing accelerator (E) is equal to or more than the aforementioned lower limit, dielectric characteristics, heat resistance, adhesion to a conductor, elastic modulus and glass transition temperature tend to be further improved. Moreover, when the content of the curing accelerator (E) is equal to or less than the aforementioned upper limit, storage stability tends to be further improved.

As necessary, the resin composition of the present embodiment may further contain one or more optional components selected from the group consisting of resin materials other than the above components, an antioxidant, a heat stabilizer, an antistatic agent, an ultraviolet absorber, a pigment, a colorant, a lubricant, and additives other than these.

Each of the above optional components may be used alone or in combination of two or more thereof.

In the resin composition of the present embodiment, the content of the above optional components is not particularly limited, and they may be used in a range where the effects of the present embodiment are not impaired, as necessary.

Further, the resin composition of the present embodiment may not contain the above optional components depending on a desired performance.

(Organic Solvent)

The resin composition of the present embodiment may contain an organic solvent from the viewpoint of facilitating handling, as well as from the viewpoint of facilitating production of a prepreg, which will be described later.

The organic solvent may be used alone or in combination of two or more thereof.

In the present specification, a resin composition containing an organic solvent is sometimes referred to as a resin varnish.

Examples of the organic solvent include an alcohol-based solvent, such as ethanol, propanol, butanol, methyl cellosolve, butyl cellosolve, and propylene glycol monomethyl ether; a ketone-based solvent, such as acetone, methyl ethyl ketone, methyl isobutyl ketone, and cyclohexanone; an ether-based solvent, such as tetrahydrofuran; an aromatic hydrocarbon-based solvent, such as toluene, xylene and mesitylene; a nitrogen atom-containing solvent, such as dimethylformamide, dimethylacetamide and N-methylpyrrolidone; a sulfur atom-containing solvent, such as dimethylsulfoxide; and an ester-based solvent, such as γ-butyrolactone.

Of these, from the viewpoint of solubility, an alcohol-based solvent, a ketone-based solvent, a nitrogen atom-containing solvent, and an aromatic hydrocarbon-based solvent are preferred, an aromatic hydrocarbon-based solvent is more preferred, and toluene is even more preferred.

When the resin composition of the present embodiment contains an organic solvent, although the solid content concentration of the resin composition is not particularly limited, it is preferably 30 to 90% by mass, more preferably 35 to 80% by mass, further preferably 40 to 60% by mass. When the solid content concentration is within the aforementioned range, the handling of the resin composition tends to be easier, and the impregnating property into a base material and the appearance of the produced prepreg tend to be further improved. In addition, it becomes easier to adjust the solid content concentration of the resin in the prepreg, which will be described later, and it tends to be easier to produce a prepreg having a desired thickness.

The resin composition of the present embodiment can be produced by mixing the components (A) and (B), and other components used in combination as necessary, by a known method. When mixing, each component may be dissolved or dispersed while stirring. Further, conditions such as the order of mixing the raw materials, mixing temperature, and mixing time are not particularly limited, and may be arbitrarily set according to the type of raw materials.

The dielectric constant (Dk) of the cured product of the resin composition of the present embodiment, at 10 GHz, is not particularly limited, but is preferably 3.0 or less, more preferably 2.9 or less, further preferably 2.8 or less from the viewpoint of low transmission loss. The dielectric constant (Dk) is preferably as small as possible, and its lower limit value is not particularly limited. However, it may be, for example, 2.3 or more, may be 2.4 or more, or may be 2.5 or more in consideration of the balance with other physical properties.

The conditions for obtaining the cured product from the resin composition of the present embodiment can be the conditions described in Examples.

The above dielectric constant (Dk) is a value based on a cavity resonator perturbation method, more specifically, a value measured by a method described in the Examples.

The dielectric loss tangent (Df) of the cured product of the resin composition of the present embodiment, at 10 GHz, is not particularly limited but is preferably 0.0040 or less, more preferably 0.0030 or less, further preferably 0.0020 or less from the viewpoint of low transmission loss. The dielectric loss tangent (Df) is preferably as small as possible, and its lower limit value is not particularly limited. However, it may be, for example, 0.0010 or more, may be 0.0012 or more, or may be 0.0014 or more in consideration of the balance with other physical properties.

The conditions for obtaining the cured product from the resin composition of the present embodiment can be the conditions described in Examples.

The above dielectric loss tangent (DO is a value based on the cavity resonator perturbation method, more specifically, a value measured by a method described in the Examples.

[Prepreg]

The prepreg of the present embodiment is a prepreg containing the resin composition of the present embodiment or a semi-cured product of the resin composition.

That is, it can be said that the prepreg of the present embodiment is formed by containing the resin composition of the present embodiment. In the present specification, the term “formed by containing” means at least formed through a state of containing.

The prepreg of the present embodiment contains, for example, the resin composition of the present embodiment or a semi-cured product of the resin composition and a sheet-like fiber base material.

Although the sheet-like fiber base material is not particularly limited, it is, for example, preferably a sheet-like fiber-reinforced base material used for the purpose of reinforcing the prepreg.

As the sheet-like fiber base material contained in the prepreg of the present embodiment, known sheet-like fiber base materials used in laminated plate for various electrical insulating materials can be used.

Examples of materials for the sheet-like fiber base material include inorganic fibers, such as E glass, D glass, S glass, and Q glass; organic fibers, such as polyimide, polyester, and tetrafluoroethylene; and mixtures thereof. These sheet-like fiber base materials have shapes of, for example, woven fabrics, non-woven fabrics, robinks, chopped strand mats, surfacing mats, and the like.

The thickness of the sheet-like fiber base material is not particularly limited, but is preferably 0.01 to 0.5 mm, more preferably 0.02 to 0.3 mm, further preferably 0.03 to 0.1 mm from the viewpoint of the mechanical strength and the thinning of the prepreg.

The sheet-like fiber base material may be one having been subjected to a surface treatment with a coupling agent or the like, or may be one having been subjected to a fiber opening treatment mechanically, from the viewpoint of the impregnating property of the resin composition, and the heat resistance, moisture absorption resistance and workability at the time of forming into a laminated plate.

The prepreg of the present embodiment can be produced, for example, by impregnating or coating a sheet-like fiber base material with the resin composition of the present embodiment, and drying as necessary.

As a method of impregnating or coating a sheet-like fiber base material with the resin composition, for example, a hot melt method, a solvent method, or the like can be used.

The hot melt method is a method of impregnating or coating a sheet-like fiber base material with a resin composition that does not contain an organic solvent. Examples of one mode of the hot melt method include a method of once applying a resin composition to a coated paper having good releasability and then laminating the coated resin composition on a sheet-like fiber base material. Examples of another mode of the hot melt method include a method of directly applying a resin composition to a sheet-like fiber base material using a die coater or the like.

The solvent method is a method of impregnating or coating a sheet-like fiber base material with a resin composition containing an organic solvent. Specifically, examples thereof include a method of immersing a sheet-like fiber base material in a resin composition containing an organic solvent and then drying the base material. By drying, the organic solvent is removed and the resin composition is semi-cured (B-staged) to obtain the prepreg of the present embodiment.

The concentration of the solid content derived from the resin composition in the prepreg of the present embodiment is not particularly limited, but is preferably 20 to 90% by mass, more preferably 25 to 80% by mass, further preferably 30 to 75% by mass from the viewpoint of obtaining better moldability when a laminated plate is formed.

The thickness of the prepreg of the present embodiment is not particularly limited, but is preferably 0.01 to 0.5 mm, more preferably 0.02 to 0.3 mm, further preferably 0.03 to 0.1 mm from the viewpoint of the moldability and enabling the high-density wiring.

[Resin Film]

The resin film of the present embodiment is a resin film containing the resin composition of the present embodiment or the semi-cured product of the resin composition.

That is, it can be said that the resin film of the present embodiment is formed by containing the resin composition of the present embodiment.

The resin film of the present embodiment can be produced, for example, by applying the resin composition of the present embodiment containing an organic solvent, that is, a resin varnish, to a support and drying by heating.

Examples of the support include a plastic film, metal foil, and release paper.

Examples of the plastic film include: polyolefin films such as polyethylene, polypropylene, and polyvinyl chloride; polyester films such as polyethylene terephthalate [hereinafter, referred to as “PET” in some cases], and polyethylene naphthalate; polycarbonate films, and polyimide films.

Examples of the metal foil include copper foil and aluminum foil.

The support may be subjected to a surface treatment such as a matting treatment or a corona treatment. Further, the support may be subjected to a release treatment with a silicon resin-based releasing agent, an alkyd resin-based releasing agent, a fluorine resin-based releasing agent or the like.

The thickness of the support is not particularly limited, but is preferably 10 to 150 μm, more preferably 20 to 100 μm, further preferably 25 to 50 μm from the viewpoint of handleability and economic efficiency.

As for a coating device for coating the resin varnish, for example, a coating device known to those skilled in the art, such as a comma coater, a bar coater, a kiss coater, a roll coater, a gravure coater, and a die coater can be used. These coating devices may be properly selected according to the film thickness to be formed.

The drying condition after the resin varnish is applied may be appropriately determined according to the content of the organic solvent, the boiling point and the like, and is not particularly limited.

For example, in the case of a resin varnish containing 40 to 60% by mass of an aromatic hydrocarbon-based solvent, the drying temperature is not particularly limited, but is preferably 50 to 200° C., more preferably 100 to 190° C., further preferably 150 to 180° C. from the viewpoint of the productivity and appropriate B-staging of the resin composition of the present embodiment.

Further, in the case of the resin varnish, the drying time is not particularly limited, but is preferably 1 to 30 min, more preferably 2 to 15 min, further preferably 3 to 10 min from the viewpoint of the productivity and appropriate B-staging of the resin composition of the present embodiment.

[Laminated Plate]

The laminated plate of the present embodiment is a laminated plate including a cured product of the resin composition of the present embodiment or a cured prepreg and a metal foil.

That is, it can be said that the laminated plate of the present embodiment is formed by containing the resin composition or the prepreg of the present embodiment and a metal foil.

A laminated plate having a metal foil is sometimes referred to as a metal-clad laminated plate.

The metal of the metal foil is not particularly limited; however, from the viewpoint of conductivity, it is preferably copper, gold, silver, nickel, platinum, molybdenum, ruthenium, aluminum, tungsten, iron, titanium, chromium, or an alloy containing one or more of these metal elements, more preferably copper and aluminum, and still more preferably copper.

The laminated plate of the present embodiment can be produced, for example, by placing metal foil on one surface or both surfaces of the prepreg of the present embodiment, and then performing molding with heating and pressurization. At that time, only one prepreg may be used, or two or more may be laminated in use.

The heating temperature for the molding with heating and pressurization is not particularly limited, but is preferably 100 to 300° C., more preferably 150 to 280° C., further preferably 200 to 250° C.

The heating and pressurization time for the molding with heating and pressurization is not particularly limited, but is preferably 10 to 300 min, more preferably 30 to 200 min, further preferably 80 to 150 min.

The pressure for the molding with heating and pressurization is not particularly limited, but is preferably 1.5 to 5 MPa, more preferably 1.7 to 3 MPa, further preferably 1.8 to 2.5 MPa.

Meanwhile, these conditions can be appropriately adjusted according to the types of raw materials to be used, and the like, and are not particularly limited.

[Printed Wiring Board]

The printed wiring board of the present embodiment is a printed wiring board including one or more selected from the group consisting of a cured product of the resin composition of the present embodiment, a cured product of the prepreg of the present embodiment, and the laminated plate of the present embodiment.

That is, it can be said that the printed wiring board of the present embodiment is formed by containing one or more selected from the group consisting of the resin composition of the present embodiment, the prepreg of the present embodiment, and the laminated plate of the present embodiment.

The printed wiring board of the present embodiment includes at least a structure containing a cured product of the resin composition of the present embodiment, a cured product of the prepreg of the present embodiment, or the laminated plate of the present embodiment, and a conductor circuit layer.

The printed wiring board of the present embodiment can be produced by subjecting one or more selected from the group consisting of, for example, a cured product of the resin composition of the present embodiment, a cured product of the prepreg of the present embodiment, a cured product of the resin film of the present embodiment, and the laminated plate of the present embodiment to conductor circuit formation by a known method. Moreover, a multiplayer printed wiring board can also be produced by further subjecting to a multilayer adhesion process as necessary. The conductor circuit can be formed by properly performing, for example, drilling, metal plating, etching of metal foil, or the like.

[Semiconductor Package]

The semiconductor package of the present embodiment is a semiconductor package including a printed wiring board of the present embodiment, and a semiconductor element. The semiconductor package of the present embodiment can be produced by, for example, mounting a semiconductor element, a memory, etc. on the printed wiring board of the present embodiment through a known method.

### EXAMPLE

The present embodiment will be specifically described below with reference to the following Examples. However, the present embodiment is not limited to the following Examples.

In each example, the number average molecular weight was measured by the following procedure.

(Method of Measuring Number Average Molecular Weight)

The number average molecular weight was converted from a calibration curve using standard polystyrene by gel permeation chromatography (GPC). The calibration curve was approximated according to a cubic expression using standard polystyrene: TSKstandard POLYSTYRENE (Type: A-2500, A-5000, F-1, F-2, F-4, F-10, F-20, F-40) [a trade name, manufactured by Tosoh Corporation]. Measurement conditions of GPC are as follows.

[GPC Measurement Conditions]

Apparatus: High-speed GPC apparatus HLC-8320GPC

Detector: UV absorption detector UV-8320 [manufactured by Tosoh Corporation]

Column: Guard column; TSK Guard column SuperHZ-L+ column; TSKgel SuperHZM-N+TSKgel SuperHZM-M+TSKgel SuperH-RC (trade names, all manufactured by Tosoh Corporation)

Column size: 4.6×20 mm (guard column), 4.6×150 mm (column), 6.0×150 mm (reference column)

Eluent: Tetrahydrofuran

Sample concentration: 10 mg/5 mL

Injection volume: 25 μL

Flow rate: 1.00 mL/min

Measurement temperature: 40° C.

(Measurement of Vinyl Group Modification Rate)

In Production Examples to be described later, a solution containing the components (b1) and (b2) before the start of a reaction and a solution after the reaction were measured by GPC using the aforementioned method, and a peak area derived from the component (b2) before and after the reaction was determined. Thereafter, the vinyl group modification rate of the component (b2) was calculated by the following formula. The vinyl group modification rate corresponds to a reduction rate of the peak area derived from the component (b2) due to the reaction.

vinyl group modification rate (%)=[(the component (b2)−derived peak area before the start of reaction)−(the component (b2)−derived peak area after the end of reaction)]×100/(the component (b2)−derived peak area before the start of reaction)

(Measurement of 25° C. Tensile Elastic Modulus)

A test piece with a width of 10 mm, a length of 80 mm, and a thickness of 0.2 mm was prepared from a resin as a measurement target, and for the test piece, both ends of the test piece in a long side direction were held between upper and lower grippers such that the distance between the grippers was 60 mm. Next, by using an autograph (AG-X, manufactured by Shimadzu Corporation), the 25° C. tensile elastic modulus of the test piece was acquired under the condition of a tensile speed of 5 mm/min, under a room temperature environment adjusted to 25° C. Five similar samples were prepared, and the tensile elastic modulus at 25° C. were acquired under the same conditions as above, and then the average value thereof was taken as the 25° C. tensile elastic modulus of the resin. Other detailed conditions and the tensile elastic modulus calculation method were carried out in accordance with International Standard ISO 5271(1993).

[Production of Modified Conjugated Diene Polymer]

### Production Examples 1 to 2

Each raw material and toluene as an organic solvent were put in amounts noted in Table 1 into a glass-made flask vessel capable of being heated and cooled, which had a volume of 2 L, and was equipped with a thermometer, a reflux condenser and a stirrer. Then, these were allowed to react with each other with stirring at 90 to 100° C. for 5 h under a nitrogen atmosphere to obtain solutions of modified conjugated diene polymers 1 and 2 (solid content concentration: 35% by mass). Table 1 illustrates the vinyl group modification rate and the number average molecular weight of the obtained modified conjugated diene polymer.

TABLE 1

| | | | Production | Production |
|---|---|---|---|---|
| | | | Example 1 | Example 2 |
| Number of modified conjugated diene polymer | | | 1 | 2 |
| (b1) | Polybutadiene 1 | parts by | 33.8 | 33.5 |
| Component | | mass | | |
| (b2) | Bismaleimide | parts by | 1.43 | |
| Component | compound 1 | mass | | |
| | Bismaleimide | parts by | | 1.48 |
| | compound 2 | mass | | |
| Reaction | Organic peroxide | parts by | 0.035 | 0.035 |
| catalyst | | mass | | |
| Physical | Vinyl group | % | 40 | 40 |
| properties | modification rate | | | |
| | Number average | — | 1,700 | 1,900 |
| | molecular weight | | | |

The details of each component described in Table 1 are as follows.

[Component (b1)]
Polybutadiene 1: a 1,2-polybutadiene homopolymer, number average molecular weight=1,200, vinyl group content=85% or more

[Component (b2)]
Bismaleimide compound 1: an aromatic bismaleimide compound including an indane ring (number average molecular weight=1,300)
Bismaleimide compound 2: bis(3-ethyl-5-methyl-4-maleimidephenyl)methane

[Reaction Catalyst]
Organic peroxide: α,α′-bis(t-butylperoxy)diisopropyl benzene

[Production of Resin Composition]

### Examples 1 to 8, and Comparative Examples 1 to 3

Components described in Table 2 were blended together with toluene according to blending amounts described in Table 2, and then were stirred and mixed at 25° C. or with heating to 50 to 80° C. to prepare a resin composition having a solid content concentration of about 50% by mass. In Table 2, the unit of the blending amount of each component is parts by mass, and in the case of a solution, it means parts by mass in terms of solid content.

[Production of Resin Film and Resin Sheet with Copper Foil on Both Sides]

The resin composition obtained in each example was applied to a PET film with a thickness of 38 μm (a product name: G2-38, manufactured by Teijin Limited) and then dried by heating at 170° C. for 5 min to prepare a resin film in a B-stage state. The resin film was peeled from the PET film, and then was pulverized to obtain resin powder in a B-stage state.

The above-obtained resin powder was put into a die-cut Teflon (registered trademark) sheet with a size of a thickness of 1 mm×a length of 50 mm×a width of 35 mm, and a low-profile copper foil with a thickness of 18 m (product name: 3EC-VLP-18 manufactured by MITSUI MINING & SMELTING CO., LTD.) was arranged above and below the sheet. Further, the low-profile copper foil was arranged with the M surface facing the resin powder. Subsequently, this laminate, which had not been subjected to molding with heating and pressurization, was subjected to molding with heating and pressurization under conditions of a temperature of 230° C., a pressure of 2.0 MPa, and a time of 120 min, so that through molding and curing of the resin powder on the resin sheet, the resin sheet with copper foil on both sides was produced. The thickness of the resin sheet portion of the obtained resin sheet with copper foil on both sides was 1 mm.

[Measurement and Evaluation Method]

The resin sheets with copper foil on both sides, which were obtained in Examples and Comparative Examples, were used to perform each measurement and evaluations according to the following methods. Table 2 illustrates the results.

(1. Method of Measuring Dielectric Constant and Dielectric Loss Tangent of Cured Product)

The resin sheet with copper foil on both sides, which was obtained in each example, was immersed in a 10% by mass solution of ammonium persulfide (a copper etching solution, manufactured by Mitsubishi Gas Chemical Co., Ltd.) to remove the copper foil and to prepare a test piece of 2 mm×50 mm. Then, the dielectric constant (Dk) and the dielectric loss tangent (Df) of the test piece were measured at an ambient temperature of 25° C., and in a 10 GHz band in accordance with a cavity resonator perturbation method.

(2. Method of Measuring Peel Strength)

The copper foil of the resin sheet with copper foil on both sides, which was obtained in each example, was processed into a straight line with a width of 5 mm by etching, and then dried at 105° C. for 1 h. This was taken as a test piece. Then, in accordance with JIS C6481:1996, the straight line-shaped copper foil formed on the test piece was pulled and peeled in a 900 direction so as to measure the peel strength of the copper foil. The measurement was performed by using “EZ-Test/CE” manufactured by Shimadzu Corporation, and the tensile speed was set as 50 mm/min when the copper foil was pulled and peeled.

TABLE 2

| | | | Example | | | | | | | | Comparative Example | | |
|---|---|---|---|---|---|---|---|---|---|---|---|---|---|
| | | | 1 | 2 | 3 | 4 | 5 | 6 | 7 | 8 | 1 | 2 | 3 |
| (A) | An aromatic bismaleimide | | 33.2 | 33.2 | 33.2 | 33.2 | 33.2 | 33.2 | 14.2 | 14.2 | | | |
| Compo- | compound including an | | | | | | | | | | | | |
| nent | indane ring | | | | | | | | | | | | |
| (A′) | Biphenylaralkyl-type | | | | | | | | | | 33.2 | 33.2 | 14.2 |
| Compo- | maleimide compound | | | | | | | | | | | | |
| nent | | | | | | | | | | | | | |
| (B) | (B1)Component: conjugated | | 14.2 | | | | | | | | | | |
| Compo- | diene polymer | | | | | | | | | | | | |
| nent | (B2)Component: modified | | | 14.2 | | | | | 14.2 | | | | |
| | conjugated diene polymer 1 | | | | | | | | | | | | |
| | (B2)Component: modified | | | | | | | | | 14.2 | 14.2 | | 14.2 |
| | conjugated diene polymer 2 | | | | | | | | | | | | |
| | (B3)Component: styrene-based | | | | 14.2 | | | | 19.0 | 19.0 | | 14.2 | 19.0 |
| | elastomer | | | | | | | | | | | | |
| | (B4)Component: polyphenylene | | | | | 14.2 | | | | | | | |
| | ether-based resin | | | | | | | | | | | | |
| | (B5)Component: silicon-based | | | | | | 14.2 | | | | | | |
| | resin | | | | | | | | | | | | |
| | (B6)Component: epoxy resin | | | | | | | 14.2 | | | | | |
| (C) | Spherical silica (average | | 47.3 | 47.3 | 47.3 | 47.3 | 47.3 | 47.3 | 47.3 | 47.3 | 47.3 | 47.3 | 47.3 |
| Compo- | particle size 0.5 μm) | | | | | | | | | | | | |
| nent | | | | | | | | | | | | | |
| (D) | Tris-diethylphosphinic acid | | 4.1 | 4.1 | 4.1 | 4.1 | 4.1 | 4.1 | 4.1 | 4.1 | 4.1 | 4.1 | 4.1 |
| Compo- | aluminum | | | | | | | | | | | | |
| nent | | | | | | | | | | | | | |
| (E) | Dicumyl peroxide | | 1.2 | 1.2 | 1.2 | 1.2 | 1.2 | 1.2 | 1.2 | 1.2 | 1.2 | 1.2 | 1.2 |
| Compo- | | | | | | | | | | | | | |
| nent | | | | | | | | | | | | | |
| Evalua- | Dielectric | Dielectric | 2.65 | 2.67 | 2.61 | 2.65 | 2.67 | 2.69 | 2.65 | 2.65 | 2.73 | 2.71 | 2.69 |
| tion | character- | constant | | | | | | | | | | | |
| result | istics | (Dk) | | | | | | | | | | | |
| | (10 GHz) | Dielectric | 0.0016 | 0.0016 | 0.0018 | 0.0017 | 0.0019 | 0.0017 | 0.0015 | 0.0014 | 0.0020 | 0.0018 | 0.0018 |
| | | loss | | | | | | | | | | | |
| | | tangent | | | | | | | | | | | |
| | | (Df) | | | | | | | | | | | |

| | | | | | | | | | | | |
|---|---|---|---|---|---|---|---|---|---|---|---|
| Peel strength (kN/m) | 0.60 | 0.65 | 0.70 | 0.60 | 0.55 | 0.55 | 0.65 | 0.55 | 0.50 | 0.50 | 0.50 |

The details of each component illustrated in Table 2 are as follows.

[Component (A)]
An aromatic bismaleimide compound including an indane ring: number average molecular weight=1,300

[Component (A′)]
A biphenylaralkyl-type maleimide compound: product name “MIR-3000” (manufactured by Nippon Kayaku Co., Ltd.)

[Component (B)]

<Component (B1)>
A conjugated diene polymer: a 1,2-polybutadiene homopolymer, number average molecular weight=1,200, vinyl group content=85% or more, 25° C. tensile elastic modulus=0.05 GPa <Component (B2)>
A modified conjugated diene polymer 1: a modified conjugated diene polymer 1 obtained in Production Example 1, 25° C. tensile elastic modulus=0.1 GPa
A modified conjugated diene polymer 2: a modified conjugated diene polymer 2 obtained in Production Example 2, 25° C. tensile elastic modulus=0.1 GPa

<Component (B3)>
A styrene-based elastomer: product name “Tuftec (registered trademark) H1221” (manufactured by Asahi Kasei Corporation), a hydrogenated styrene-based thermoplastic elastomer (SEBS; styrene-ethylene-butylene-styrene copolymer), styrene content=12% by mass, MFR=4.5 g/10 min under measurement conditions of 230° C. and a load of 2.16 kgf, number average molecular weight=170,000, 25° C. tensile elastic modulus=0.5 GPa

<Component (B4)>
A polyphenylene ether-based resin: product name “S203A” (manufactured by Asahi Kasei Corporation.), number average molecular weight=12,000, the average number of phenolic hydroxy groups per molecule=1.8, 25° C. tensile elastic modulus=2.2 GPa

<Component (B5)>
A silicon-based resin: product name “X-22-9412” (manufactured by Shin-Etsu Chemical Co., Ltd.), polysiloxanediamine having a vinyl group, reactive group equivalent=430 g/mol, 25° C. tensile elastic modulus=0.1 GPa

<Component (B6)>
An epoxy resin: product name “HP-7200H” (DIC Corporation), a dicyclopentadiene-type epoxy resin (an epoxy resin having an alicyclic skeleton), 25° C. tensile elastic modulus=2.8 GPa

From Table 2, in the resin compositions obtained in Examples 1 to 8 of the present embodiment, the dielectric constant and the dielectric loss tangent were low, and a high peel strength was obtained. From this, it can be seen that the resin composition of the present embodiment is excellent in dielectric characteristics and conductor adhesiveness in a high frequency band of a 10 GHz band or higher. Meanwhile, the resin compositions obtained in Comparative Examples 1 to 3 were inferior in any of dielectric constant, dielectric loss tangent and peel strength, and were insufficient in achieving both dielectric characteristics and conductor adhesiveness.

### INDUSTRIAL APPLICABILITY

The cured product produced from the resin composition of the present embodiment is excellent in dielectric characteristics and conductor adhesiveness in a high frequency band of a 10 GHz band or higher. Therefore, the resin composition of the present embodiment is useful for printed wiring boards and the like used in fifth-generation mobile communication system (5G) antennas that use radio waves in the frequency band exceeding 6 GHz and millimeter-wave radars that use radio waves in the frequency band of 30 to 300 GHz.

1. A resin composition comprising:
(A) at least one selected from the group consisting of a maleimide compound including a fused ring of an aromatic ring and an aliphatic ring in a molecular structure thereof, and including two or more N-substituted maleimide groups, and its derivative; and
(B) a resin having a tensile elastic modulus of 10 GPa or less at 25° C.

2. The resin composition according to claim 1, wherein the fused ring is an indane ring.

3. The resin composition according to claim 2, wherein the indane ring is a divalent group represented by the following formula (a1-1) and is included in the component (A), 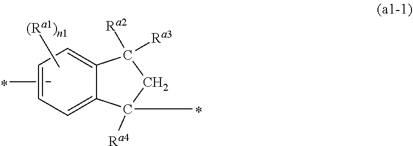
wherein R^{a1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group or a mercapto group, and n1 is an integer of 0 to 3, each of R^{a2} to R^{a4} is independently an alkyl group having 1 to 10 carbon atoms, and * represents a bonding site.

4. The resin composition according to claim 1, wherein the component (B) contains at least one selected from the group consisting of a polyolefin-based resin, a polyphenylene ether-based resin, a silicon-based resin, and an epoxy resin.

5. The resin composition according to claim 4, wherein the component (B) contains, as the polyolefin-based resin, a modified conjugated diene polymer obtained by modifying (b1) a conjugated diene polymer having a vinyl group in a side chain, with (b2) a maleimide compound having two or more N-substituted maleimide groups.

6. The resin composition according to claim 4, wherein the component (B) contains a styrene-based elastomer as the polyolefin-based resin.

7. A prepreg comprising the resin composition according to claim 1 or a semi-cured product of the resin composition.

8. A laminated plate comprising: a cured product of the resin composition according to claim 1; and metal foil.

9. A resin film comprising the resin composition according to claim 1 or a semi-cured product of the resin composition.

10. A printed wiring board comprising at least one selected from the group consisting of a cured product of the resin composition according to claim 1.

11. A semiconductor package comprising the printed wiring board according to claim 10, and a semiconductor element.
